(19) United States
(12) Patent Application Publication
(10) Pub. No.: US 2017/0352771 A1
(43) Pub. Date: Dec. 7, 2017

(54) Systems, Methods, and Apparatus for Concentrating Photovoltaic Cells

(71) Applicants: Tian GU, Fairfax, VA (US); Juejun HU, Newton, MA (US)

(72) Inventors: Tian GU, Fairfax, VA (US); Juejun HU, Newton, MA (US)

(21) Appl. No.: 15/666,219

(22) Filed: Aug. 1, 2017

Related U.S. Application Data
(63) Continuation of application No. PCT/US2016/021182, filed on Mar. 7, 2016.
(60) Provisional application No. 62/128,699, filed on Mar. 5, 2015.

(51) Int. Cl. H01L 31/054; H01L 31/0687; H01L 31/18

(52) U.S. Cl. CPC H01L 31/0543; H01L 31/1804; H01L 31/0547; H01L 31/0687

(57) ABSTRACT

A photovoltaic (PV) apparatus includes a substrate having a first substrate surface and a second substrate surface. A cavity fabricated in the substrate extends from the first substrate surface toward the second substrate surface. The cavity defines a first end to receive incident light, a second end opposite the first end, and a side surface, which extends from the first end to the second end to concentrate the incident light, received by the first end, toward the second end. The PV apparatus also includes a photovoltaic (PV) cell, in optical communication with the second end of the at least one cavity, to convert the incident light into electricity.

### CROSS-REFERENCES TO RELATED APPLICATIONS

This application is a continuation application of International Application No. PCT/US2016/021182, filed Mar. 7, 2016, entitled “Systems, Methods, and Apparatus for Concentrating Photovoltaic Cells,” which claims priority to U.S. Application No. 62/128,699, filed Mar. 5, 2015, entitled “WAFER-LEVEL MICRO-OPTICAL SENSING AND METHODS FOR MAKING THE SAME.” Each of these applications is hereby incorporated herein by reference in its entirety.

### BACKGROUND

Concentrating photovoltaics (CPV) systems use refractive and/or reflective optical components to concentrate sunlight onto high performance solar cells (e.g., multijunction cells), thereby reducing material and processing costs of solar cells and improving the conversion efficiency. Since CPV modules typically provide high efficiency output, area-related costs can also be reduced due to the decreased usage of total area, such as balance-of-system and land usage, among others.

Several issues may hinder the development of CPV technologies. One issue originates from limited concentration and acceptance angle and the challenge to collect diffuse light. Another issue relates to practical difficulties, including, but are not limited to, complexity of fabrication, integration and installation of the CPV systems, complexity and size of optical systems, tight misalignment tolerance, use of high-precision trackers, and thermal management.

Micro-concentrating PV (MCPV) scales down the dimensions of conventional concentrated PV cells (e.g., on the order of 100 microns in diameter) and the concentrating optics from millimeters to microns. Compared to conventional flat panel silicon PV, MCPV have the potential to integrate arrays of PV cells and concentrating optics more closely within a single module, thereby providing higher conversion efficiency given the same form factor. Additional benefits of MCPV include reduced semiconductor and optic materials costs, enhanced solar cell performance, improved thermal management, improved interconnect flexibility, and more compact physical profiles.

Low-cost molded concentrator optical elements are typically utilized for conventional concentrated PV modules. In current practices, MPCV technologies simply miniaturize conventional CPV approaches. However, low-cost molding tools are generally not suitable for making optical components with a size of a few hundred microns or smaller. The feature size, shape, surface quality, and aspect ratio of a micro-optical component is limited by the machining tool size, geometry, and tip rounding effects. In addition, the position accuracy of optical elements during the molding process is usually on the order of 10 μm. Therefore, the tolerance to fabrication deviations can also become tight, with dimensional accuracy of about a few microns or less.

These fabrication challenges can limit the employment of efficient non-imaging optical concentrators with performance close to the thermodynamic limit in a micro-scale PV system. In terms of integration and assembly of MCPV cells, the position accuracy of the optics layer on the PV cell layer is approximately ±25 μm. Since the solar cells are usually very small (˜100 μm) and errors from desired positions can grow as a function of the number of layers, this accuracy can limit the use of multi-stage optical concentrators to improve the collection efficiency and/or illumination uniformity. The conversion efficiency of existing MCPV cells can be further reduced by diffuse light, which is usually difficult to concentrate due to its low directionality.

### SUMMARY

Embodiments of the present invention include apparatus, systems, and methods of working and using concentrating photovoltaic technologies. In one example, an apparatus includes a substrate having a first substrate surface and a second substrate surface. The substrate defines at least one cavity extending from the first substrate surface toward the second substrate surface. The at least one cavity defines a first end to receive incident light, a second end opposite the first end, and a side surface, extending from the first end to the second end, to concentrate or direct the incident light, received by the first end, toward the second end. A photovoltaic (PV) cell is in optical communication with the second end of the at least one cavity to convert the incident light into electricity. An optical adhesive layer may be positioned between the PV cell and the second end of the at least one cavity.

In another example, a method of making a photovoltaic (PV) device includes etching a substrate to form at least one cavity extending from a first substrate surface of the substrate toward a second substrate surface of the substrate. The at least one cavity defines a first end to receive incident light, a second end opposite the first end, and a side surface, extending from the first end to the second end, to concentrate or direct the incident light received by the first end toward the second end. The method also includes coupling a PV cell to the second end of the at least one cavity.

In yet another example, a photovoltaic (PV) device includes a silicon substrate having a first substrate surface and a second substrate surface. A micro-lens array is disposed on the first substrate surface to focus incident light toward the first substrate surface. The silicon substrate defines an array of cavities having a pitch of about 0.1 mm to about 10 mm. Each cavity in the array of cavities extends from the first substrate surface toward the second substrate surface. Each cavity also defines a first end to receive the incident light from the micro-lens array, a second end opposite the first end, and a side surface to concentrate or direct the incident light received by the first end toward the second end. The PV device also includes an array of PV cells (such as multi junction PV cells), disposed in optical communication with the second end of a respective cavity in the array of cavities, to convert the incident light into electricity.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 shows a schematic of a photovoltaic (PV) apparatus using a wafer-level concentrating element.

FIG. 2 shows a schematic of a PV apparatus using a concentrator defined by a cavity fabricated within a substrate and a PV cell disposed on the bottom surface of the cavity.

FIG. 3 shows a schematic of a PV apparatus using a concentrator fabricated on a substrate.

FIG. 4 shows a perspective view of a PV apparatus using a pyramid-shape concentrator defined by a cavity fabricated in a substrate.

FIGS. 5A-5B illustrate a PV apparatus including a wafer-level concentrator and an additional concentrator that can be molded or pre-fabricated.

FIGS. 6A-6B illustrate a PV apparatus including an array of PV elements, each of which includes a wafer-level concentrator and an additional concentrator that can be molded or pre-fabricated.

FIG. 7 shows a perspective view of a flexible PV apparatus including wafer-level concentrators.

FIGS. 8A-8D illustrate a PV apparatus including a first substrate for fabricating wafer-level concentrators and a second substrate for mechanical support or electrical coupling.

FIGS. 9A-9D show a PV apparatus including a silicon substrate for fabricating wafer-level concentrators and a Polydimethylsiloxane (PDMS) layer including additional concentrators.

FIGS. 10A-10D show a PV apparatus including wafer-level concentrators disposed on one side of a glass layer and a PDMS layer including additional concentrators disposed on the other side of the glass layer.

FIGS. 11A-11D show a PV apparatus including wafer-level concentrators fabricated in a silicon layer, a PDMS layer, and a poly(methyl methacrylate) (PMMA) layer including additional concentrators.

FIGS. 12A-12B show a PV apparatus including wafer-level concentrators fabricated in a substrate and an optical layer including both refractive and reflective concentrators.

FIGS. 13A-13B show a PV apparatus including PV cells to collect diffuse light.

FIGS. 14A-14B show a PV apparatus including a cascade of PV cells.

FIGS. 15A-15B show a PV apparatus including a ball lens (or a cylinder lens) that acts as an additional concentrator and an alignment element.

FIGS. 16A-16B show a PV apparatus including an array of PV element, each of which includes a ball lens (or a cylinder lens) that acts as an additional concentrator and alignment element.

FIG. 17 shows a cross sectional view of a PV apparatus including multiple layers of concentrating elements.

FIGS. 18A-18B show an apparatus using cavities and balls (or cylinders) as alignment elements.

FIGS. 19A-19B show an apparatus including an additional concentrating element with integrated alignment elements.

FIGS. 20A-20B show an apparatus including wafer-level concentrating elements and alignment elements.

FIGS. 21A-21C illustrate a method of fabricating a PV apparatus including wafer-level concentrating elements.

FIGS. 22A-22B illustrate a method of fabricating cavities in silicon substrates as wafer-level concentrating elements.

FIGS. 23A-23C illustrate a method of fabricating a PV apparatus including throughout cavities as wafer-level concentrating elements.

FIGS. 24A-24F illustrate a method of fabricating a PV apparatus including wafer-level concentrating elements and a back substrate.

FIGS. 25A-25G illustrate a method of fabricating a PV apparatus including wafer-level concentrating elements and alignment elements.

FIGS. 26A-26C are simulation results of ray traces in an apparatus including wafer-level concentrating elements.

FIGS. 27A-27B are simulation results of ray traces in an apparatus including two stages of light concentrating elements.

FIGS. 28A-28B are simulation results of ray traces in an apparatus including two stages of light concentrating elements and an additional reflective concentrator.

FIG. 29 shows comparisons of baseline systems including wafer-level concentrating elements with state-of-the-art micro-/mini-CPV technologies.

FIGS. 30A-30C show simulations of PV systems with and without wafer-level concentrating elements.

FIGS. 31A-31C show simulation results of a PV system with respect to direct/global irradiation ratios.

FIG. 32 show simulation results of optical losses in a PV system including wafer-level concentrating elements.

### DETAILED DESCRIPTION

### Overview

To address, at least partially, challenges in conventional concentrating photovoltaic (PV) technologies, systems, apparatus, and methods described herein employ an approach that integrates wafer-level micro-optical concentrating elements with micro-scale solar cells to enhance conversion efficiency, reduce material and fabrication costs, and significantly reduce system form factors. In this approach, a multi-functional platform is constructed by fabricating wafer-level micro-concentrating elements in or on a substrate. The concentrating element can include, for example, cavities etched in a silicon substrate, wedge- or pyramid-shaped silicon pieces, and micro-lenses, among others. Semiconductor etching techniques can fabricate features with high precision on the order to nanometers, much greater than the precision achieved in conventional techniques used for manufacturing micro-concentrating PV cells.

This multi-functional platform can seamlessly integrate hybrid photovoltaics, optical micro-concentration, and mechanical micro-assembly in one substrate, particularly designed for high-performance, low-cost micro-scale concentrating photovoltaics. For example, a multi-functional platform can be fabricated from active silicon (e.g., ˜160 μm thick standard crystalline Silicon wafers used in the solar industry). Micro-PV cells (e.g., high-efficiency multi junction micro-PV cells on the order of 100 microns in diameter) can be bonded to the multi-function platform to receive concentrated direct sunlight, while the multi-function platform itself collects diffuse sunlight or light not collected by the micro-PV cell, thereby increasing conversion efficiency and allowing all-weather operation of the resulting PV devices.

In addition, efficient non-imaging micro-optical concentrating elements (e.g., two-dimensional reflective cavity arrays) can be directly fabricated in the silicon substrate using standard PV fabrication processes to reduce the usage of multi junction cells while providing sufficient angular and spatial tolerances. Such elements can also be used as precise alignment features for micro-assembly of the Si substrate to molded micro-concentrator arrays (in addition to the wafer-level concentrating elements) and other opto-mechanical components. Therefore, multiple layers of concentrating optics can be integrated into the resulting PV device to further increase the concentration ratio, which can reduce the use of expensive multi junction PV cells.

The approach described herein can address several dilemmas in current PV industry. For example, it is usually desirable to increase the geometric concentration ratio of PV cells to reduce materials costs, but normally at the price of reducing the acceptance angle of concentrating PV devices, resulting in tight tolerance to angular misalignment and increased module- and system-level costs (e.g., requirements for high-precision manufacturing/integration processes and high-accuracy but expensive solar trackers). This compromise can be addressed by using multi-stage non-imaging optics to improve the overall concentration ratio×acceptance angle product. In another example, increasing the size and complexity of concentrator systems usually leads to increased efficiency but also quickly induces costs. Due to its high position accuracy, a wafer-level etched concentrator can be easily integrated with multiple layers of simple molded plastic optics, thereby effectively controlling the total cost. In yet another example, hot spots can arise when the concentration ratio is high. These hot spots may be eliminated by advanced lens surfaces and non-imaging optic design that redistribute focused light while maintaining a good acceptance angle.

Based on the wafer-level micro-concentrating elements fabricated directly within a substrate, a fully-integrated hybrid micro-CPV device can be constructed to offer the high performance of CPV and the flat profile of conventional flat panel PV. Some advantages of these devices include: i) integration of electrical, micro-optical, and micro-mechanical functionalities on a single low-cost thin platform; ii) higher concentration-acceptance angle products; iii) collecting and converting diffuse light under a hybrid micro-CPV architecture; and iv) low-cost in fabrication and assembly.

PV Apparatus Including Wafer-Level Concentrating Elements

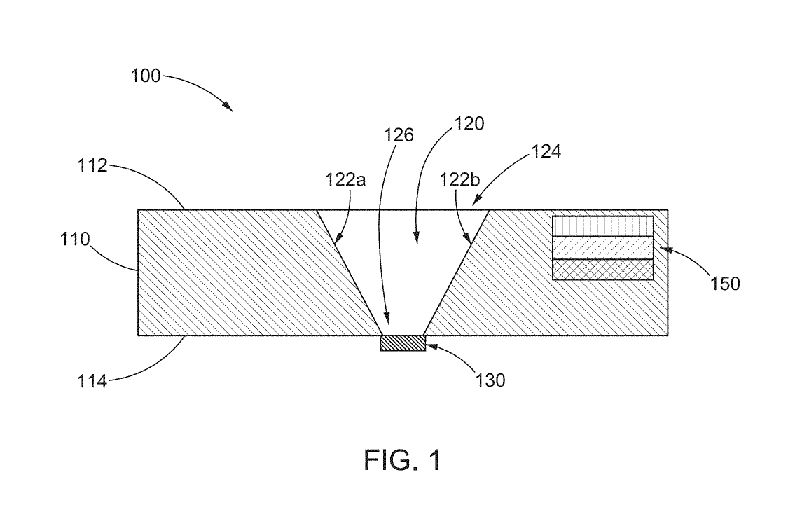

FIG. 1 shows an apparatus 100 including a wafer-level concentrating element for photovoltaic conversion. The apparatus 100 includes a substrate 110 which has a front surface 112 and a back surface 114. A cavity 120 is fabricated in the substrate 110 to function as an example of concentrating elements to concentrate or direct incident light. The cavity 120 has an entrance end 124 on one end, an exit end 126 on the other, and side surfaces 122a and 122b (collectively referred to as side surface 122) that connect the entrance end 124 with the exit end 126. Incident light for photovoltaic conversion is received by the entrance end 124 and reflected by the side surfaces 122 toward the exit end 126, where a PV cell 130 is disposed to convert the incident light into electricity. Since the entrance end 124 is larger than the exit end 126, incident light is concentrated by the side surfaces 122 such that the PV cell 130 can have a smaller size and lower cost. From another perspective, the side surfaces 122 can also reflect or direct obliquely incident light towards the PV cell 130 and thus improve acceptance angle or field-of-view of the PV system.

Various materials can be used for the substrate 110 to form the cavity 120. In general, it is beneficial to use semiconductor material in order to take advantage of existing etching technologies. In one example, the substrate 110 includes silicon, such as single crystalline silicon, poly-crystalline silicon, or amorphous silicon. In another example, the substrate 110 includes germanium. In yet another example, the substrate 110 includes a compound semiconductor material such as a III-V semiconductor (e.g., GaAs and InP, among others).

The substrate 110 can be inactive (no p-n junction) and provide mechanical support for the cavity 120 or any other component in prospective PV devices. In another example, the substrate 110 can include p-n junctions or additional PV cells. FIG. 1 shows one p-n junction 150 (not to scale) formed in the substrate. In practice, the substrate 110 can include multiple p-n junctions. In this case, the substrate 110 can include low cost materials (e.g., silicon) and the PV cell 130 can use more efficient and more costly materials (e.g., III-V semiconductor). As a result, the PV cell 130 can receive concentrated light, and the substrate 110, which functions as another PV cell (because of the p-n junctions) to collect and convert diffuse light or light not collected by the PV cell 130. This hybrid architecture can improve performance of the apparatus 100 without incurring significantly higher cost (at least because the substrate material is less expensive than the PV cell 130). Based on U.S. solar radiation data from “National Solar Radiation Data Base”, the hybrid approach can produce 40-60% and 20-40% more energy per unit area than Si flat panel PV and CPV, respectively.

The cavity 120 functions as a concentrating element that reflects incident light received by the entrance end 124 toward the exit end 126 and the PV cell. The incident light can arrive at the PV cell 130 after one or more reflections so the cavity 120 can be non-imaging optics suitable for solar energy concentration. To this end, the cavity 120 can have various shapes. In one example, the cavity 120 can be one-dimensional (1D), such as a V-shaped groove. In another example, the cavity 120 can be two-dimensional (2D). For example, the cavity 120 can have a pyramid shape with four side surfaces 122 (two sides surfaces 122a and 122b are shown in FIG. 1). In another example, the cavity 120 can have a cone shape with one continuous side surface 122 (in this case the side surfaces 122a and 122b shown in FIG. 1 merge into one surface). In yet another example, the cavity 120 can have a spherical or paraboloidal shape. In these cases, the side surfaces 122 can focus or direct the incident light. The focal point can be re-distributed over the PV cell 130 so that the entire area of the PV cell 130 is illuminated. In yet another example, the cavity 120 can be formed by the [111] crystal plane of the substrate 110 when silicon is used as the substrate 110.

The side surfaces 122 can be coated with a reflective layer (not shown in FIG. 1) to increase the reflectivity and therefore the optical efficiency of the cavity 120. The reflective coating can include, for example, aluminum, silver, gold, or any other reflective material known in the art. In another example, the PV cells 130 can be disposed or formed on the side surfaces of the cavity 120, to collect and convert at least a portion of the light incident on the side surfaces.

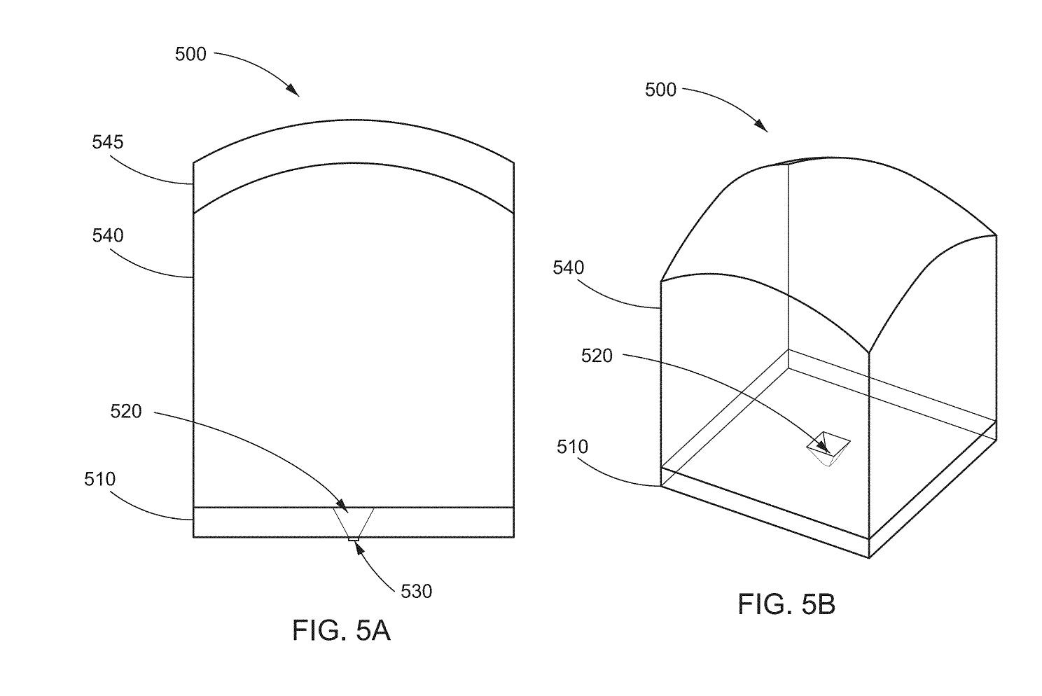

In one example, the cavity 120 can be filled with air or vacuum. In another example, the cavity 120 can be filled with one or more other dielectric materials, such as Ethylene vinyl acetate (EVA), Epoxy, poly(methyl methacrylate) (PMMA), Polydimethylsiloxane (PDMS), water, or oil. The filling material that immerses the PV cell 130 can increase the concentration ratio and acceptance angle of the apparatus 100 to, compared to CPV systems with PV cells immersed in air or vacuum. The acceptance angle of the PV apparatus 100 can be defined as the maximum angle at which incoming sunlight can be captured by the PV cell 130. Filling a dielectric material into the cavity 120 can decrease the index refractive difference between the cavity 120 and other components in the apparatus including additional concentrators disposed above the cavity 120 (e.g., see FIGS. 5A-5B). The filling material can also improve the mechanical stability of the apparatus 100 by providing mechanical support to other components of the apparatus (e.g., the PV cell 130).

The PV cell 130 in the apparatus 100 is bonded to the back surface 114 of the substrate 110. When filling material is used, the PV cell 130 can also be bonded to the filling material in the cavity 120. Since the PV cell 130 usually has a small size (e.g., on the order of 50 μm, 100 μm, or 200 μm), material costs of expensive but efficient materials, such as III-V semiconductors, can be reduced. The typical thickness of the PV cell 130 can range from a few microns to hundreds of micron.

The cavity 120 shown in FIG. 1 extends through the substrate 110 (i.e., extending from the front surface 112 all the way to the back surface 114). In practice, various etch depths can be used.

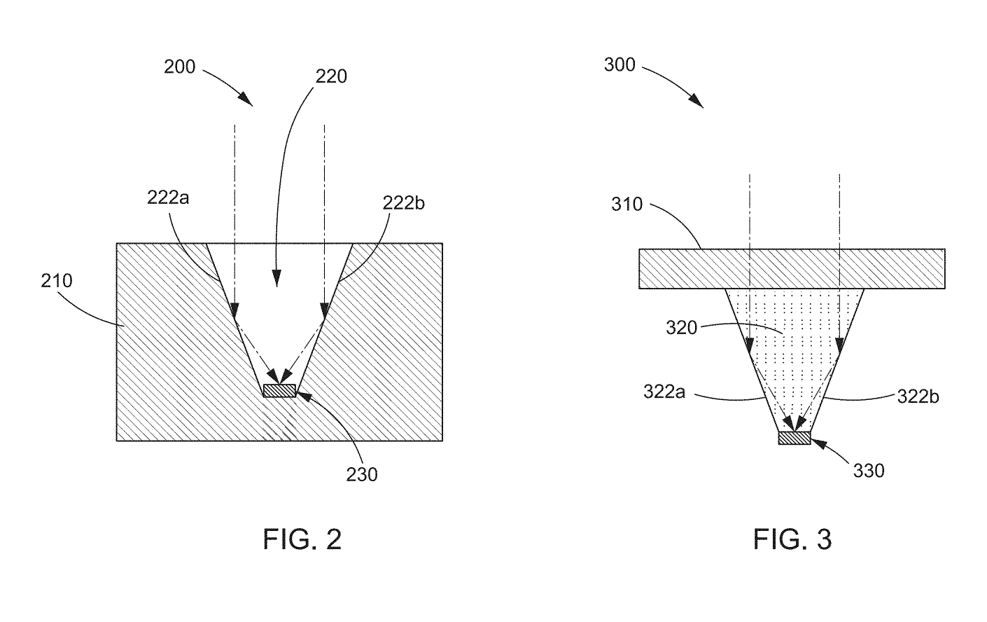

FIG. 2 shows an apparatus 200 in which a cavity 220 is etched only partially through a substrate 210. In this case, the exit end of the cavity 220 includes a bottom surface that receives a PV cell 230. Similar to the apparatus 100 shown in FIG. 1, the apparatus 200 concentrates the incident light onto the PV cell 230 via reflection from side surfaces 222a and 222b (collectively referred to as side surfaces 222). The depth (i.e., distance from the entrance end to the exit end of the cavity 220) can depend on, for example, the desired concentration ratio and the total cost of the apparatus 200 (the total cost depends on the area of the PV cell 230).

The apparatus 100 and 200 use cavities 120 and 220 as concentrating elements to concentrate light. Alternatively, the remaining portion of the substrate (the solid part), in which cavities 120 and 220 are fabricated, can also be used as the concentrating element to concentrate or redirect incident light via total internal reflection (TIR).

FIG. 3 shows a schematic of an apparatus 300 including a concentrating element 320 that includes the remaining portion of an etched substrate. In this case, the concentrating element 320 can considered the “complement” of the cavities 120 and 220 shown in FIGS. 1 and 2. The concentrating element 320 can have shapes such as pyramid, paraboloid, cone, hemisphere, or any other shape applicable here. Incident light received by the concentrating element 320 are reflected by side surfaces 322a and 322b via internal reflection. A front substrate 310 is included in the apparatus 300 to, for example, provide mechanical support for the concentrating element 320. A PV cell 330 is disposed at the smaller end of the concentrating element 320 to receive concentrated incident light for electricity conversion.

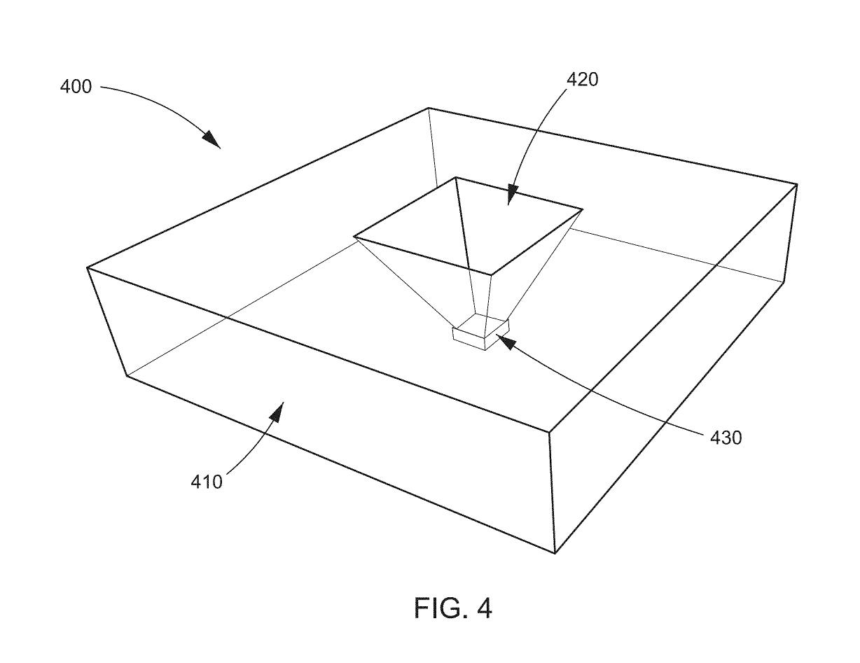

FIG. 4 shows a perspective view of a PV apparatus 400 including a wafer-level concentrating element. The apparatus 400 includes a substrate 400, in which a cavity 420 is fabricated as the concentrating element. A PV cell 430 is disposed at the smaller end of the cavity 420 (e.g., either on the bottom surface if the cavity 420 is partially through the substrate 410 or on the back surface of the substrate 410 if cavity 420 goes through the substrate 420). The cavity 420 has an inverted pyramid shape for illustrating and non-limiting purposes only. In practice, various other shapes, such as cone, sphere, and paraboloid can also be used.

PV Apparatus Including Multi-Stage Concentrating Elements

To further increase the concentrating ratio, which can be defined as the ratio of the area of incident light over the area of the concentrated light received by the PV cell, additional concentrating elements can be included in the apparatus shown in FIGS. 1-3. Since the cavity micro-concentrating element embedded at the wafer level can improve concentration ratio and acceptance angle, it can accordingly facilitate the fabrication and assembly of additional optical components to be integrated with the wafer-level concentrators to form robust multi-stage optical concentrating systems. As introduced before, the high precision of semiconductor etching techniques employed for fabricating the wafer-level concentrating elements also help precise alignment with other components such as additional concentrating optics.

FIGS. 5A-5B show a cross sectional view and a perspective view, respectively, of an apparatus 500 including two levels of concentrating elements. The apparatus 500 includes a substrate 510 in which a cavity 520 is fabricated as a wafer-level concentrating element. A PV cell 530 is disposed at the exit of the cavity 530. An additional concentrating element 540, which may include a coating layer 545 (e.g., anti-reflection coating or structures), is disposed on the substrate 510 to concentrate incident light toward the entrance of the cavity 520. The aperture (e.g., the area of the receive surface) of the additional concentrating element 540 is larger than the entrance of the cavity 520, which is further larger than the PV cell 530. Therefore, the incident light across a wide range of incident angles can be directed or concentrated twice in a cascade manner from the additional concentrating element 540 toward the PV cell 530, where the received light is converted into electricity. Note that FIGS. 5A-5B are not to scale. In practice, the additional concentrating element 540 can be more than 50 times wider than the PV cell 530 (e.g., 100 times larger, 500 larger, 1000 times larger, 1500 times larger, 3000 times larger, or even greater).

The additional concentrating element 540 is usually much larger than the wafer-level concentrating element (i.e., cavity 520) and the PV cell 530, for example, about 0.5 mm to about 100 mm in diameter or other lateral dimension. On this size scale, various techniques can be used to manufacture the additional concentrating elements 540 such as molding, polishing, lithography, etching, or any other techniques known in the art.

The additional concentrating element 540 can include either imaging optics or non-imaging optics. In one example, the additional concentrating element 540 includes a lens that can concentrate or direct the incident light toward the entrance of the cavity 520. Since the incident light focused by micro-lens is usually directional, the cavity 520 can concentrate the received incident light with good efficiency. In another example, the additional concentrating element 540 includes at least one curved reflective mirror (such as a parabolic mirror) that concentrates or directs the incident light toward the entrance of the cavity 520.

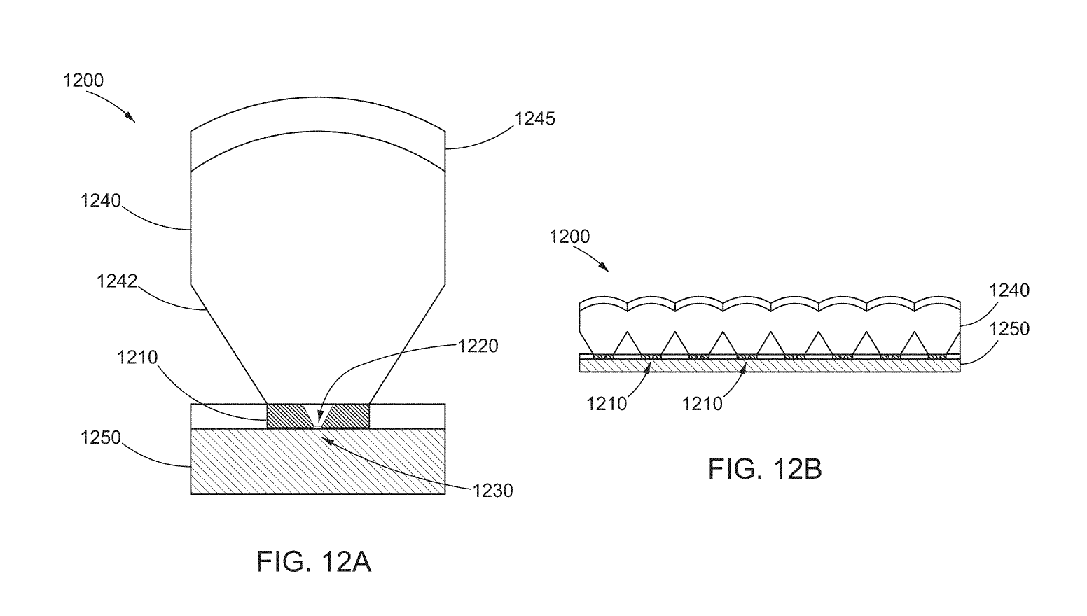

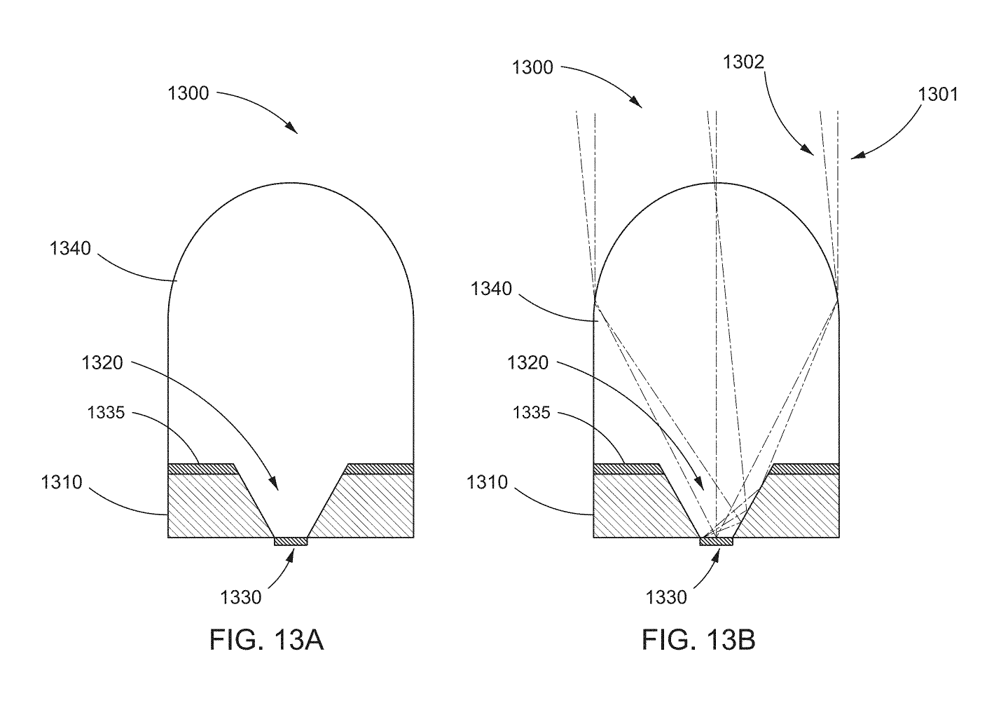

In another example, the additional concentrating element 540 can be non-imaging (e.g., another cavity-like structure as shown in FIGS. 12A-12B). In this case, the additional element 540 may cause some incident to become not directional and difficult to be concentrated by the cavity 520. However, this issue can be addressed by at least two approaches. In one approach, the substrate 510 can include active silicon or other solar cell material such that the substrate 510 can function as another PV cell to collect and convert diffuse light or light not directed towards the PV cell 530. In another approach, additional PV cells can be disposed on the interface between the substrate 510 and the additional concentrating element to collect diffuse light or light not directed towards the PV cell 530 (see, e.g., FIGS. 13A-13B). In yet another example, additional PV cells can be disposed on the side surfaces of the cavity. In yet another example, a combination of imaging and non-imaging optical components can be used.

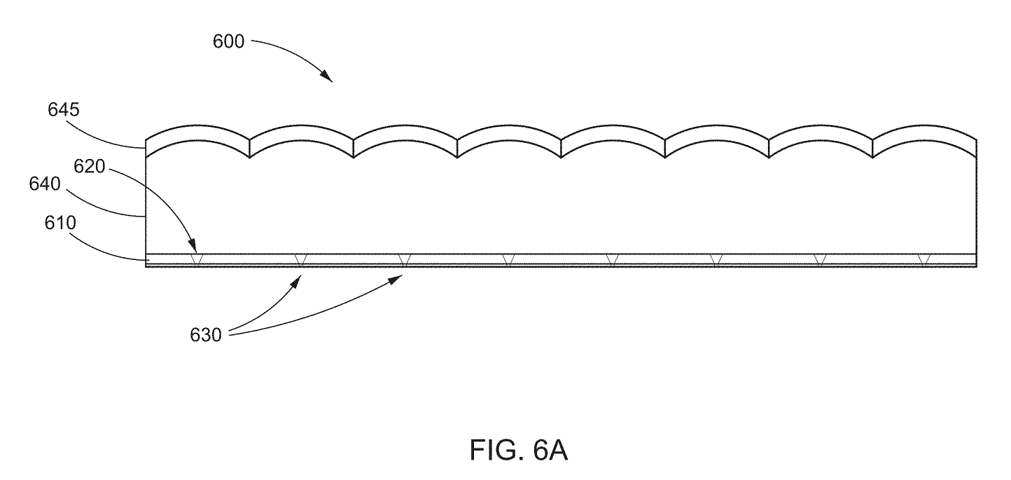

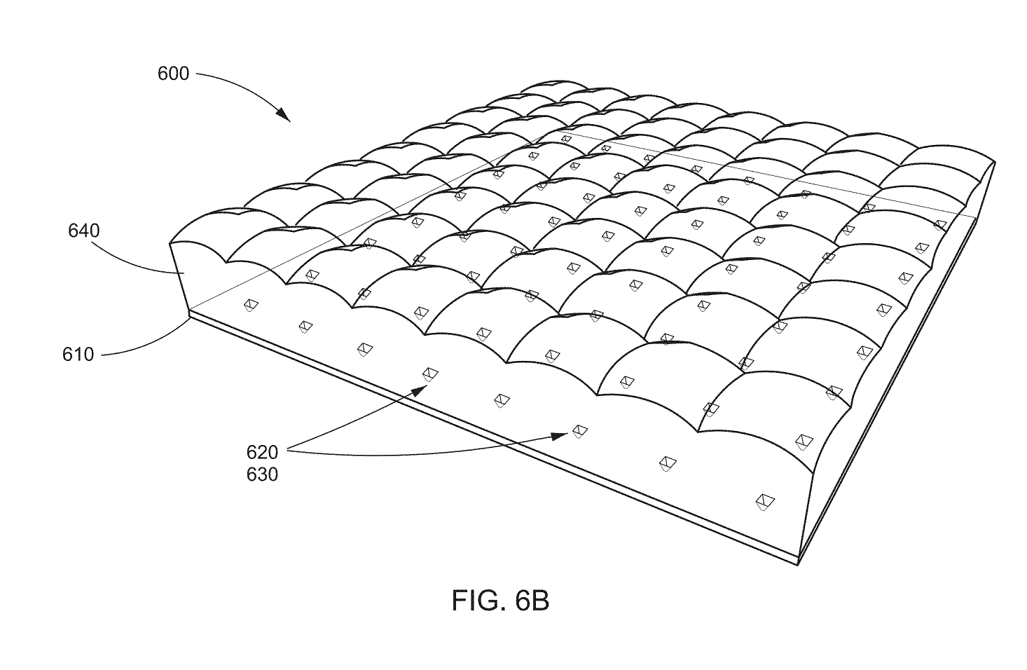

FIGS. 6A-6B show a cross sectional view and a perspective view, respectively, of a PV apparatus 600 including an array of PV elements, each of which is substantially similar to the structure as shown in FIGS. 5A-5B. The apparatus 600 includes a substrate layer 610 in which a plurality of cavities 620 are fabricated. On the exit end of each cavity 620 is disposed a PV cell 630. An additional concentrating layer 640 is disposed on the substrate layer 610 to receive incident light. The additional concentrating layer 640 can optionally include a coating layer 645.

In one example, the additional concentrating layer 640 includes a molded micro-lens array, which is precisely aligned and assembled on the top of the cavities 620. The resulting apparatus 600 can be compact and have a flat physical profile. Integrated with PV cells 630, the wafer-embedded micro-concentrator structure, including the cavities 620 and the additional concentrating layer 640, can act as an efficient two-stage non-imaging concentrator with a simple optical architecture.

The cavities 620 and the corresponding PV cells 630 in the apparatus 600 can be substantially periodic. The period (also referred to as pitch) of the cavities 620 and the PV cells 630 can be about 0.1 mm to about 100 mm (e.g., about 0.1 mm, 0.5 mm, 1 mm, 5 mm, 10 mm, 20 mm, 50 mm, and 100 mm). The aperture (diameter or other lateral dimension) of each element (e.g., micro-lens) in the additional concentrating layer 640 can be substantially equal to the period of the cavities 620. The PV cells 630 are smaller than the aperture of additional concentrating element and can be about 10 μm to about 2 mm (e.g., about 10 μm, 20 μm, 50 μm, 100 μm, 200 μm, 500 μm, 1 mm, and 2 mm).

The overall size of the apparatus 600 can depend on the application of the apparatus 600. For example, the apparatus 600 can be used for consumer electronics, such as a cellphone or watch, in which case the size of the apparatus 600 can be on the order to 1 inch. In another example, the apparatus 600 can be used to generate electricity for a utility. In this case, the apparatus 600 can be on the order of several feet to tens of feet.

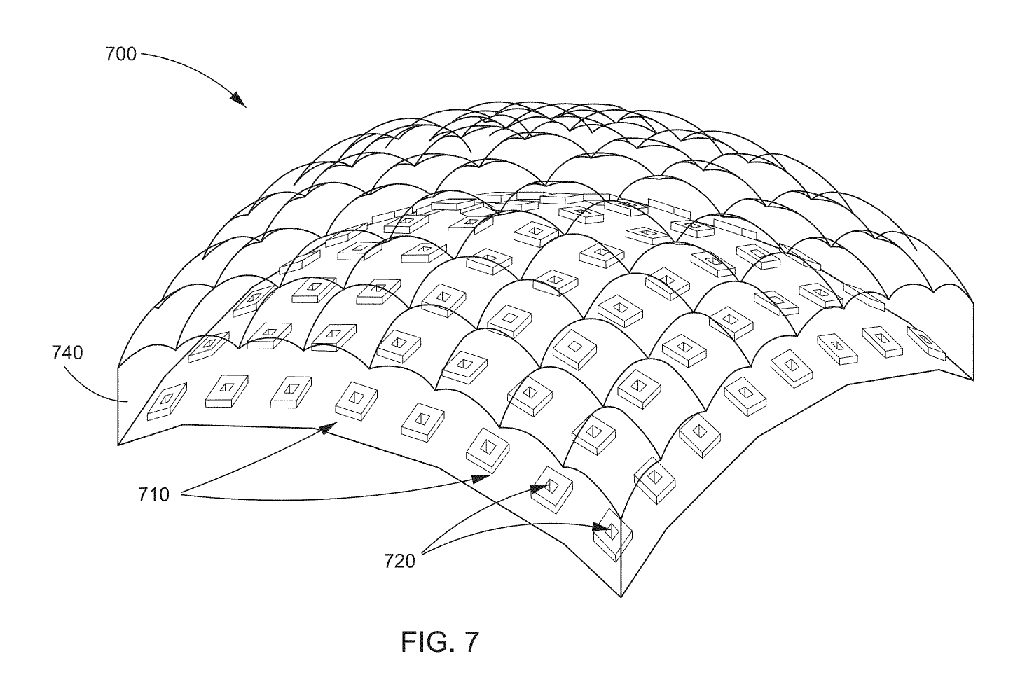

FIG. 7 shows an apparatus 700 including an array of silicon substrates 710. A cavity 720 is fabricated in each silicon substrate 710 as the wafer-level concentrating element. An additional concentrating layer 740 is disposed on the array of silicon substrates 710 to receive incident light. The additional concentrating layer 740 also includes an array of concentrating elements, each of which corresponds to one silicon substrate 710 (and one cavity 720). In FIG. 7, each cavity 720 is fabricated in its respective silicon substrate 710. In another example, an array of cavities can be fabricated in one substrate which is subsequently singulated to form an array of substrates 710 each containing a cavity 720. The substrate array 710 can be assembled on a substrate or a superstrate. The substrate or superstrate may be rigid or flexible. For one example, the additional concentrating layer 740 can be made of flexible material such as PDMS or PMMA and act as a superstrate for the silicon substrate array 710. The resulting apparatus 700 is therefore also flexible and can be used in more applications. For example, the apparatus 700 can be conformally disposed on a non-flat surface to fit the shape of electronics to be powered. In another example, the apparatus 700 can be used in wearable technologies (e.g., wearable devices). Alternatively, when the flexibility of the apparatus 700 is of less concern, a monolithic substrate can be used to fabricate the array of cavities 720.

PV Apparatus Including a Back Substrate

As described above, a PV apparatus can include an array of wafer-level concentrating elements such as cavities, each of which is coupled to a PV cell. These wafer-level concentrating elements can be either fabricated out of a monolithic semiconductor substrate or fabricated on different individual substrates (i.e., an array of substrates is used to match the array of PV cells). In this case, it can be helpful to employ a back substrate to hold together the array of wafer-level concentrating elements. In addition, this back substrate can also provide physical protection, moisture protection, and electrical connection among internal devices and to external devices. Alternative, electrical components (such as interconnects) can be formed directly on the silicon substrate itself.

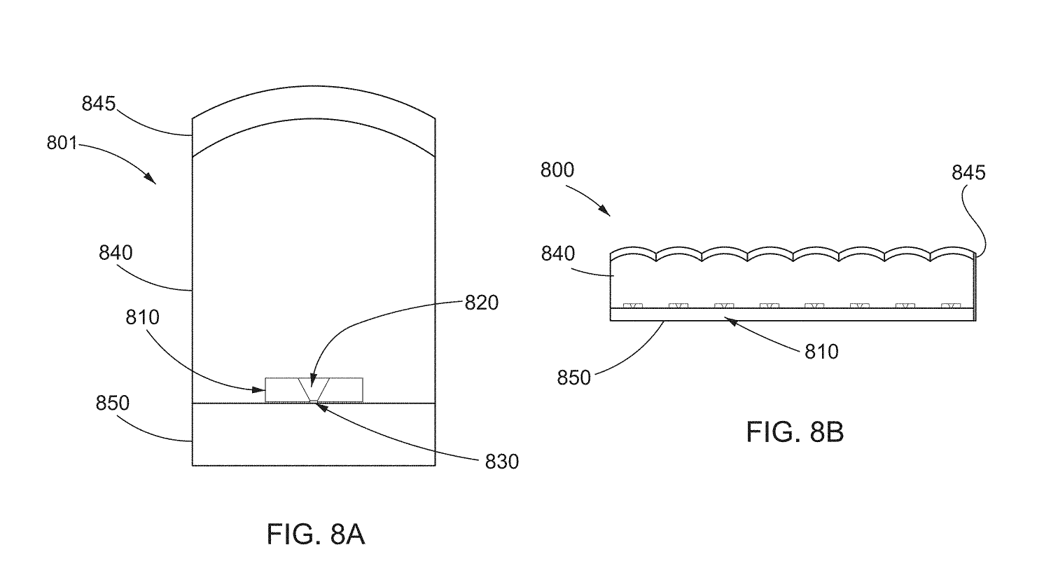

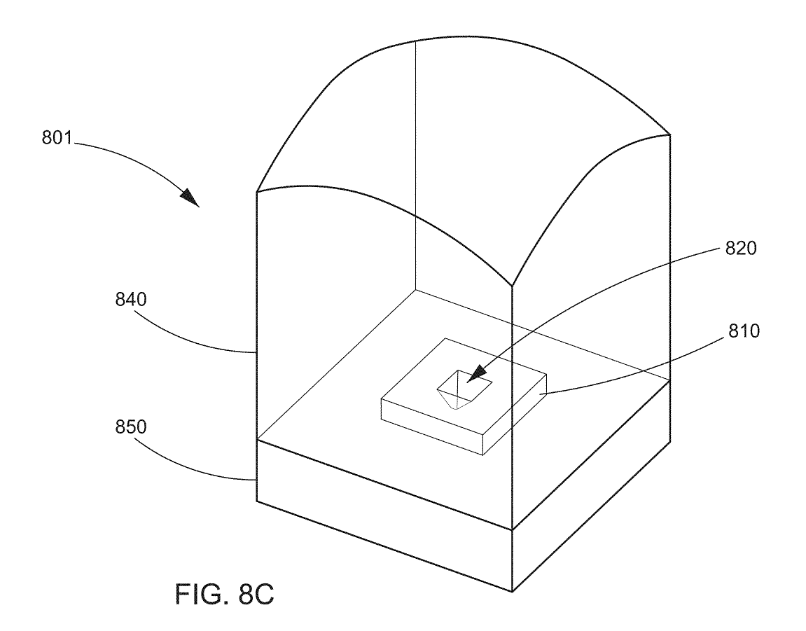

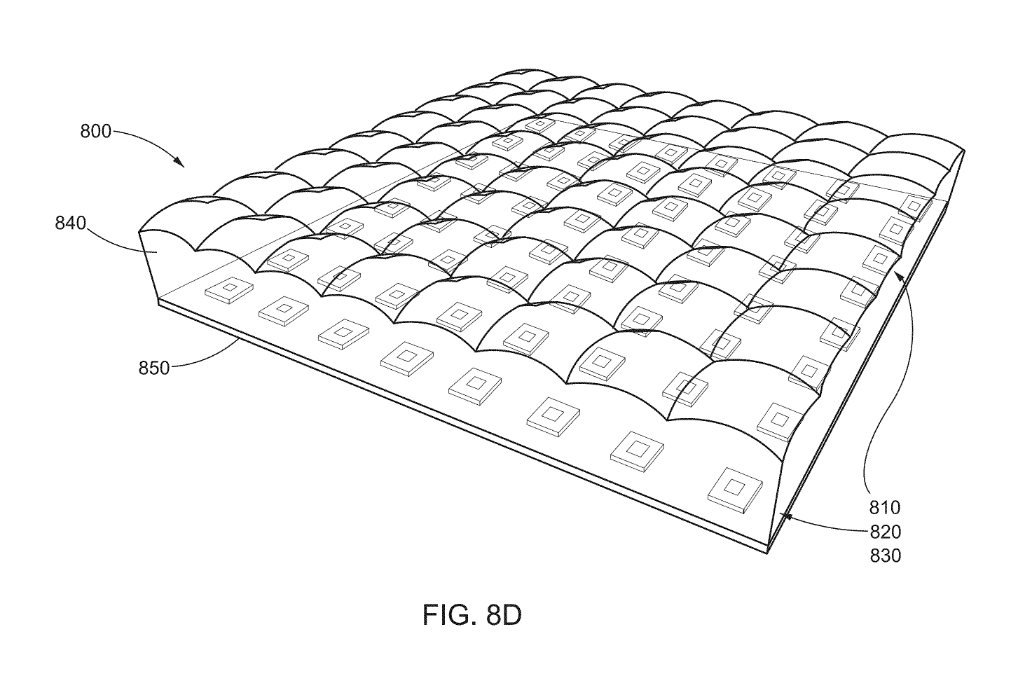

FIGS. 8A-8D illustrate an apparatus 800 including a back substrate 850. FIG. 8A shows a cross sectional view of one cell 801 in an array of PV cells 800. FIG. 8B shows the cross sectional view of the apparatus 800. FIG. 8C and FIG. 8D show a perspective view of one individual cell 801 and the entire apparatus 800, respectively. The apparatus 800 (and the individual cell 801) includes a primary substrate 810 in which a cavity 820 is fabricated. A PV cell 830 is disposed at the exit end of the cavity 820. For convenience, one combination of these three elements 810, 820, and 830 is collectively referred to as one integrated PV element. The integrated PV element is sandwiched between an additional concentrating element 840 and a back substrate 850. FIG. 8B and FIG. 8D show that the apparatus 800 includes an array of integrated PV elements, each of which includes a respective primary substrate 810, a cavity 820, and a PV cell 830. Both the additional concentrating element 840 and the back substrate 850 are monolithic, extending across the array of integrated PV elements.

In one example, the back substrate 850 includes a glass plate to provide mechanical support to other components in the apparatus 800. Electrical components (such as interconnects) can be positioned on the glass plate. In another example, the back substrate 850 includes a printed circuit board to electrically couple the plurality of PV cells 830 with external devices that the PV cells 830 can power. In yet another example, the back substrate 850 includes a backsheet, which can protect and connect the apparatus 800 to other electronic components as readily understood in the art. One benefit of using micro-scale PV cells is that as the cell size reduces below about 1 mm, the ratio between the cell total surface area and its aperture area increases dramatically, which can improves thermal dissipation, thereby allowing the utilization of a much wider range of substrate materials compared to conventional CPV approaches.

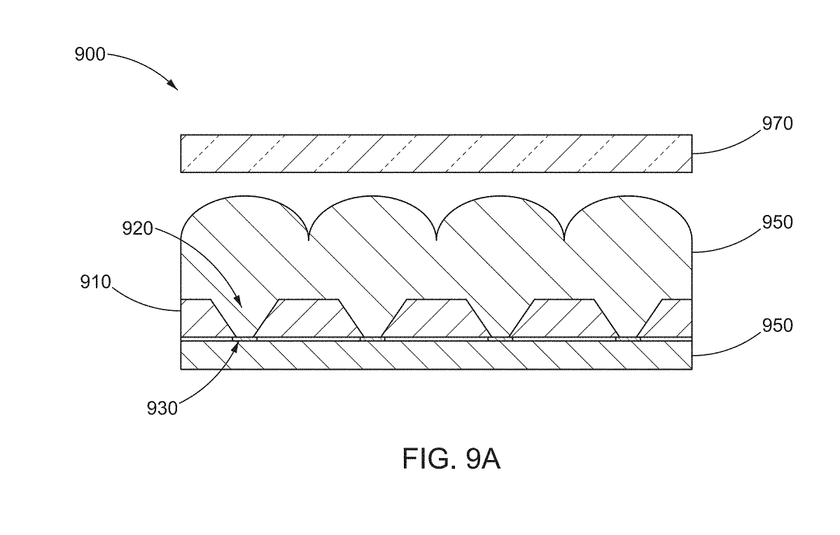

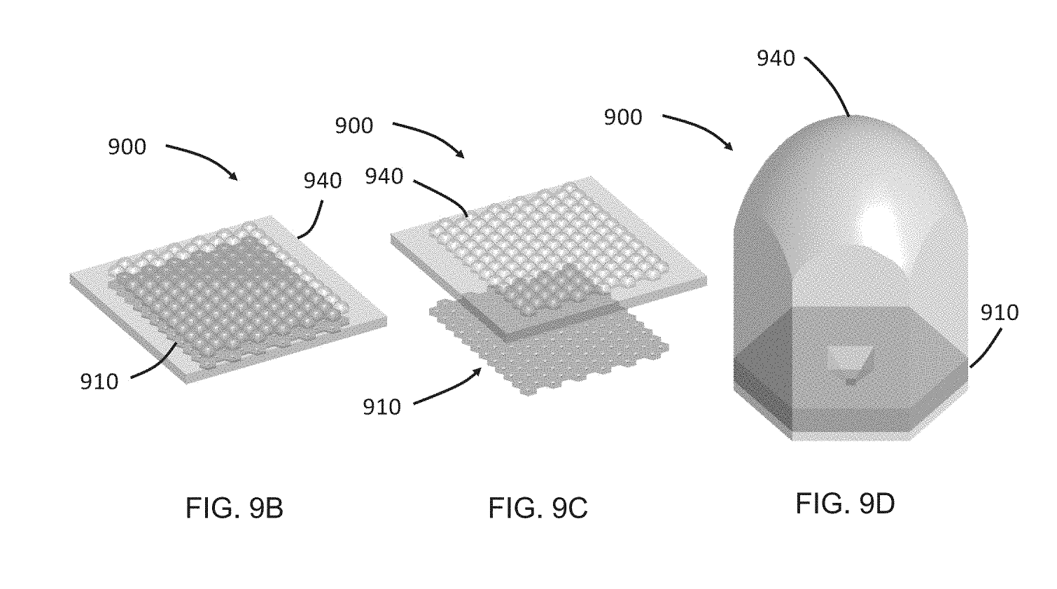

FIGS. 9A-9D show a PV apparatus 900 including a back substrate 950 on which wafer-level concentrating elements and an additional concentrating layer are disposed. FIG. 9A shows a cross sectional view of the apparatus 900 including a silicon substrate 910 in which a plurality of cavities 920 are fabricated. For each cavity 920, a PV cell is disposed at the narrower end of the cavity 920. The combination of silicon substrate 910, the cavities 920, and the PV cells 930 is sandwiched between an additional concentrating layer 940 and a back substrate 950. The additional concentrating layer 940 includes a micro-lens array made of optical materials such as PDMS, PMMA, BK7, etc. A diffractive optic (e.g., a Fresnel lens) can be utilized as well. Each micro-lens in the micro-lens array is aligned with a respective cavity 920 and a PV cell 930. The back substrate 950 shown in FIG. 9A includes a backsheet. A front glass 970 is disposed above the additional concentrating layer 940 to protect all the components below the front glass 970. The front glass 970 may have anti-reflection coatings to improve its optical transmission. The substrate 910 can be a PV cell.

The plurality of cavities 920 can be either fabricated out of a single piece of silicon substrate 910 or formed in multiple pieces of silicon substrates as described above, depending on, for example, the desired flexibility of the resulting apparatus 900. As shown in the FIG. 9A, the cavities 920 are filled with optical materials such as PDMS, which constitutes the additional concentrating layer 940 as well. This filling can improve optical performance (e.g., concentration and acceptance angle), provide mechanical support to the PV cells 930, and improve the overall integration (e.g., mechanical stability) of the apparatus 900.

FIG. 9B and FIG. 9C show an assembled view and an exploded view, respectively, of the apparatus 900. For illustrating purposes only, a monolithic silicon substrate is used to fabricate the array of cavities 920. The additional concentrating elements 940 also form a monolithic layer, which can be made of optical materials (such as PDMS, PMMA, BK7) via, for example, molding techniques. In this case, the two layers can be conveniently bonded together to form the apparatus 900.

FIG. 9D shows an individual PV cell in the apparatus 900 including an array of such PV cells. The individual PV cell has a hexagonal contour for illustrating purposes. In practices, various other shapes can also be used, such rectangular, square, round, trapezoid, or any other shape applicable.

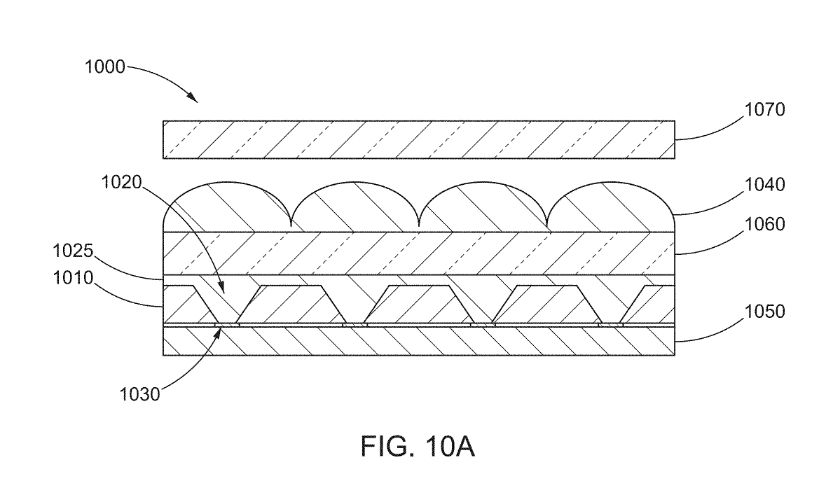

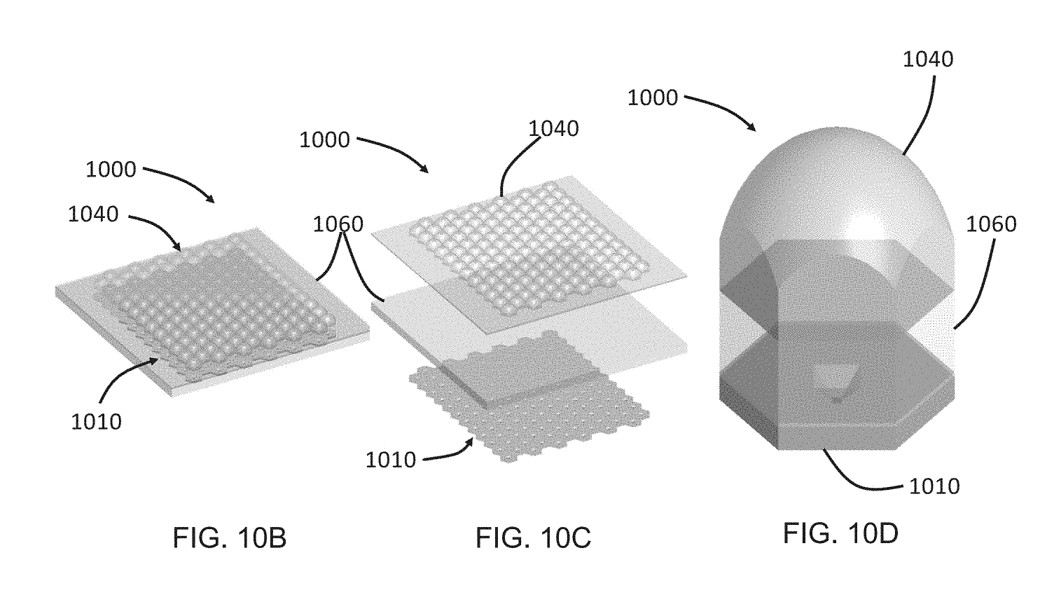

FIGS. 10A-10D show a PV apparatus 1000 including a middle sheet 1060. FIG. 10A shows a cross sectional view of the apparatus 1000, which includes a middle sheet 1060 sandwiched between an additional concentrating layer 1040 and a filling layer 1025 disposed in cavities 1020 that are fabricated in a primary substrate 1010. The middle sheet can be a piece of glass or a plastic sheet. Each cavity 1020 is also coupled to a PV cell 1030. The primary substrate 1010 is disposed on a back substrate 1050. A front glass piece 1070 is disposed on the top for protection or to act as a substrate or superstrate for other optical components.

FIG. 10B and FIG. 10C show an assembled view and an exploded view, respectively, of the apparatus 1000. As can be seen from FIGS. 10B-10C, using glass or plastic as a middle layer may facilitate the manufacturing of the apparatus 1000. More specifically, the additional concentrating layer 1040 and the primary substrate layer 1010, which may further including the PV cells, can be separately bonded to the middle sheet to form the apparatus 1000. Since the additional concentrating layer 1040 and the primary substrate layer can be soft (e.g., made of PDMS) and delicate, direct bonding between them may be challenging. Using the middle glass piece 1060 as mechanical support can therefore improve the manufacturing efficiency and reliability. FIG. 10D shows a perspective view of an individual PV cell in the apparatus 1000 including an array of such PV cells.

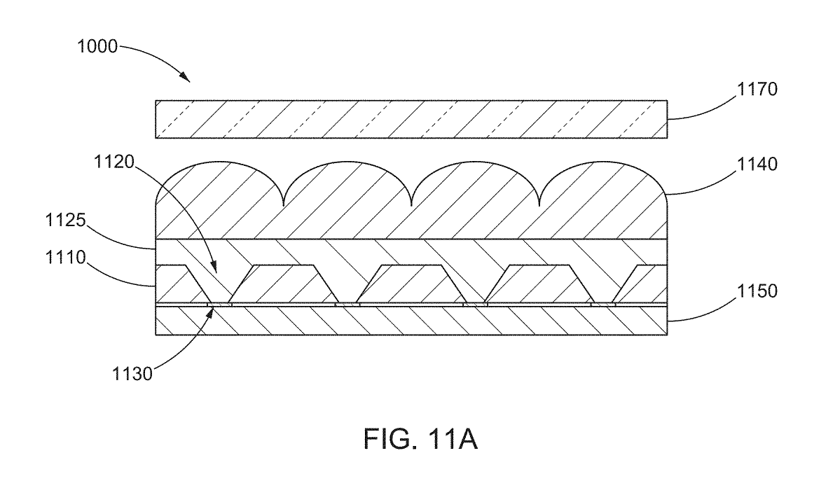

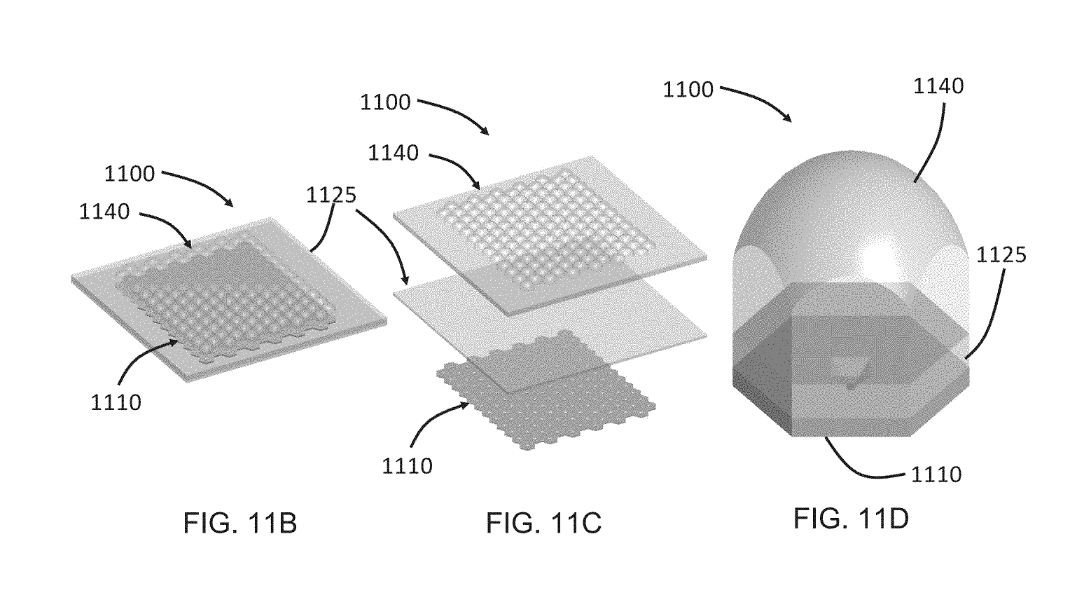

FIGS. 11A-11D shows a PV apparatus 1100 including an intermediate optical layer 1125. FIG. 11A shows a cross sectional view of the apparatus 1100, which includes an intermediate optical layer 1125 (e.g., made of PDMS) disposed in cavities 1120 that are fabricated in a primary substrate 1110. An additional concentrating layer 1140, which can be made of PMMA, is bonded to the intermediate optical layer 1125. The intermediate optical layer 1125 can provide mechanical cushion between the additional concentrating layer 1140 and the primary substrate 1110 to reduce any deformation effect. As a result, the selection of optical materials for 1140 (e.g., high refractive index molded plastic components) can be free from restriction by the material of substrate 1110. For example, by using relatively soft PDMS as the intermediate optical layer 1125, high refractive index plastic materials (e.g., PMMA) can be used as the micro-lens material to improve concentration and acceptance angle. Each cavity 1120 is also coupled to a PV cell 1130. The primary substrate 1110 is disposed on a back substrate 1150. A front glass 1170 is disposed on the top for protection purposes. FIG. 11B and FIG. 11C show the assembled view and the exploded view, respectively, of the apparatus 1100. In these views, the intermediate optical layer 1125 can be regarded as the middle layer sandwiched by the additional concentrating layer 1140 and the primary substrate 1110. FIG. 11D shows the perspective view of an individual PV cell in the apparatus 1100 including an array of such PV cells.

FIGS. 12A and 12B show a PV apparatus 1200 with a faceted optical concentrating element 1240 on a wafer-level concentrating element 1220. As shown in FIG. 12A, the apparatus 1200 includes a primary substrate 1210 and a cavity 1220 fabricated therein. A PV cell 1230 is disposed at the exit end of the cavity 1220. The combination of the primary substrate 1210, the cavity 1220, and the PV cell 1230 is sandwiched between an additional concentrating layer 1240 on the top and a back substrate 1250 on the bottom. The additional concentrating layer 1240 includes a top surface 1245 that can concentrate incident light toward the cavity 1220 either refraction (e.g., a micro-lens) or reflection (e.g., a curved mirror). The additional concentrating layer 1240 also has a side surface 1242 that can reflect incident light (e.g., via internal reflection) toward the bottom, thereby further concentrating the incident light. The side surface 1242 or facet can have various shapes such as pyramid, cone, paraboloid, or sphere, or free-form, among others.

PV Apparatus Including a Cascade of PV Cells

In practice, one layer of PV cells may not collect all the incident light because of diffuse light or finite transmission of the PV cells (i.e. part of the incident light transmits through the PV cells without being converted into electricity). Therefore, it can be beneficial to use more than one layer of PV cells in a cascade, tile, or lateral architecture to increase the conversion efficiency.

FIG. 13A shows a cross sectional view of an apparatus 1300 including a substrate 1310, in which a cavity 1320 is fabricated as a wafer-level concentrating element, and secondary PV cells 1335 to collect diffuse light so as to increase conversion efficiency. A PV cell 1330 is disposed at the exit end of the cavity 1320. An additional concentrating element 1340 is disposed on the substrate 1310 to focus, concentrate, or direct incident light toward the entrance of the cavity 1320. In addition to the PV cell 1330, the apparatus 1300 further includes the secondary PV cell(s) 1335 disposed on the front surface (the surface toward incident light) of the substrate 1310 to collect light that is received by the additional concentrating element 1340 but ends up on the substrate 1310. FIG. 13B shows the same apparatus 1300 but with illustration of ray traces. The solid lines represent rays 1301 that are directly focused onto the PV cell 1330. The dashed lines represent rays 1302 that are incident at an oblique angle and are redirected by the cavity 1320 and then received by the PV cell 1330. Rays that are not collected by the PV cell 1330 may be collected by the secondary PV cell 1335.

In one example, the secondary PV cell 1335 is disposed on the front surface of the substrate 1310 (e.g., as shown in FIG. 13A). The PV cell 1335 may also be disposed at the bottom of the substrate 1310, or be sandwiched between two substrates. In another example, the secondary PV cell 1335 can be directly fabricated in the substrate 1310. For example, the substrate 1310 can use active silicon material with p-n junctions and therefore can function as the secondary PV cell. The p-n junctions can be disposed at any position with the secondary PV cell 1335. Since the secondary PV cell 1335 generally has no concentration or low concentration, less expensive material such as silicon can be used, without significantly incurring the cost of the resulting apparatus 1300.

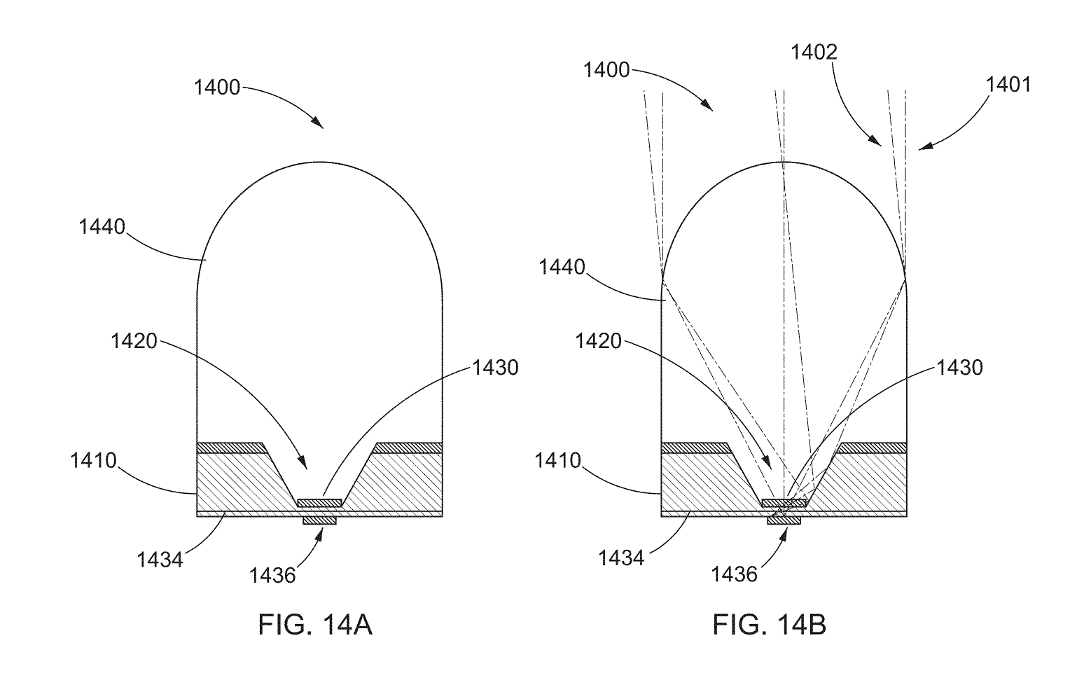

FIG. 14A shows a cross sectional view of an apparatus 1400 with a cavity 1420 fabricated in a substrate 1410. An additional concentrating element 1440 is disposed on the substrate 1410 to receive incident ray 1401 (normal incidence rays, see FIG. 14B) and 1402 (oblique incidence rays, see FIG. 14B) and focus or direct the incident rays 1401 and 1402 toward the entrance of the cavity 1420. Three layers of PV cells are disposed at the exit of the cavity 1420 to receive the focused/concentrated/directed incident light 1401 and 1402. On the first layer is a primary PV cell 1430, which can be a high efficiency PV cell such as a III-V type semiconductor solar cell. The second layer includes a non-concentrating PV cell 1434, which can be directly fabricated inside the substrate 1410 by, for example, creating p-n junctions. This non-concentrating PV cell 1434 can extend across the entire substrate 1410, collecting not only incident light transmitted through the primary PV cell 1430 but also diffuse light that arrives at the non-concentrating PV cell 1434. The third layer of PV cells includes a secondary PV cell 1436 that can also use high efficiency materials. FIG. 14B shows the same apparatus 1400 but illustrates ray traces of incident light. Solid lines indicate rays 1401 that are directly focused or directed onto the PV cell 1430 and dashed lines indicate rays 1402 incident at oblique angles that are redirected by the cavity 1420 and received by the PV cell 1430.

The primary PV cell 1430 and the secondary PV cell 1436 can have different bandgaps for converting to incident light at different wavelengths. For example, the primary PV cell 1430 can convert incident lights with shorter wavelengths (e.g., visible light) while the secondary PV cell 1436 can convert incident lights with longer wavelengths (e.g., infrared and near infrared light) that is not absorbed by the primary PV cell 1430. The primary PV cell 1430 and the secondary PV cell 1436 can also have different thickness so as to reduce recombination losses within the PV cells. For example, at the optimal thickness of the primary PV cell 1430, where recombination loss is low, the primary PV cell 1430 may not be able to absorb and convert the incident light efficiently or completely. In this case, the secondary PV cell 1436 can collect any light that is transmitted through the primary PV cell 1430 and increase the overall conversion efficiency of the apparatus 1400.

PV Apparatus Including Alignment Elements

As introduced above, a substrate fabricated with an array of cavities is a multifunctional platform that can integrate hybrid photovoltaics, optical micro-concentration, and mechanical micro-assembly in one substrate. Other than light concentration, this multi-functional platform can also allow self-alignment of micro-optical systems, including micro-photovoltaic systems.

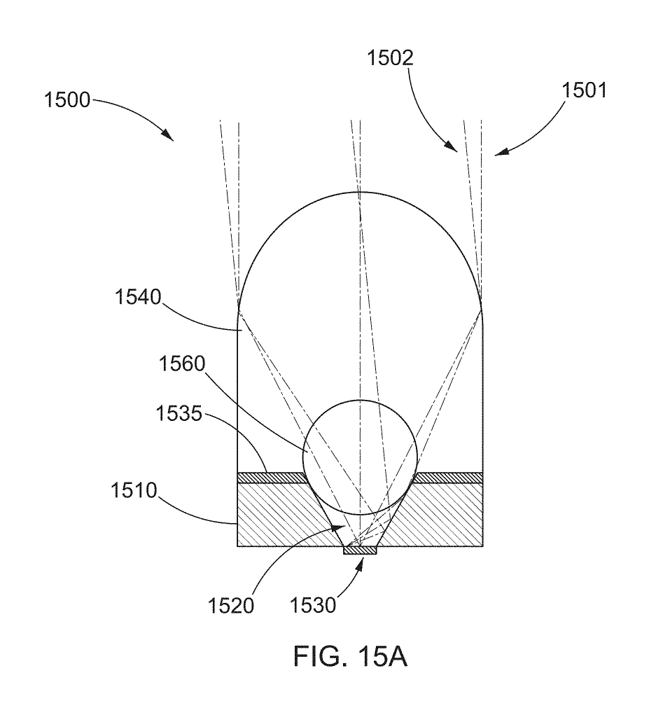

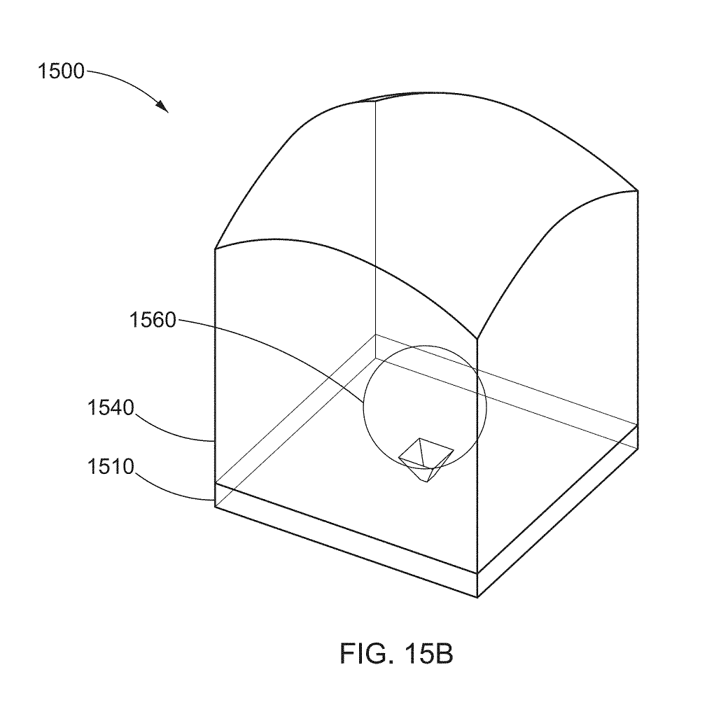

FIGS. 15A-15B shows a cross sectional view and a perspective view of an apparatus 1500 including a ball lens 1560 for both light concentration and alignment. The apparatus 1500 includes a substrate 1510 in which a cavity 1520 is fabricated for both light concentration and alignment. The entrance end of the cavity 1520 is coupled to the ball lens 1560 and the exit end of the cavity 1520 is coupled to a PV cell 1530. A secondary PV cell 1535 is sandwiched between the substrate 1510 and an additional concentrating element 1540. In another example, the secondary PV cell 1535 can be directly fabricated in the substrate 1510. For example, the substrate 1510 can use active silicon material with p-n junctions and therefore can function as the secondary PV cell. The p-n junctions can be disposed at any locations of the secondary PV cell 1535.

The additional concentrating element 1540 is configured to receive incident light, including normal incidence light 1501, oblique incidence light 1502, and diffuse light (collectively referred to as incident light). Most of the incident light concentrated by the additional concentrating element 1540 is received by the ball lens 1560. Light not received by the ball lens 1560 can be collected and converted into electricity by the secondary PV cell 1535. The ball lens 1560 further focuses the incident light into the cavity 1520. In general, the normal incidence light 1501 can be directly focused or directed onto the PV cell 1530, while the oblique incidence light 1502 can reach the PV cell 1530 after some reflection by the cavity 1520.

The additional concentrating element 1540 can be formed by plastic molding and can be either directly molded on the substrate 1510 or pre-fabricated and then assembled onto the substrate 1510. The ball lens 1560 can have a higher refractive index than the material of additional concentrating element 1540 to provide further concentration. In another example, the ball lens 1560 and the additional concentrating element 1540 can be separated by an air gap. The ball lens 1560 can be made of plastic or glass.

The ball lens 1560, in addition to concentrating light, also aligns the substrate 1510 and other optical or mechanical elements, such as the additional concentrating element 1540. For example, the additional concentrating element 1540 can be pre-fabricated and then coupled to the substrate 1510 (e.g., see FIG. 9C, 10C, and 11C). In this case, an array of holes can be made at the bottom of the additional concentrating element 1540 to fit the shape of the ball lens 1540. When coupling these layers together, the ball lens 1560 can hold the additional concentrating element 1540 in position, in a similar manner as mortise and tenon.

FIGS. 15A-15B show a ball lens 1560 (3D lens). The entrance of the cavity 1520 can have various shapes such as square, hexagon, and round, among other. In practice, the ball lens 1560 can be replaced by a cylindrical lens and accordingly the cavity 1520 can be replaced by a V-shape grove to achieve similar optical and mechanical functions.

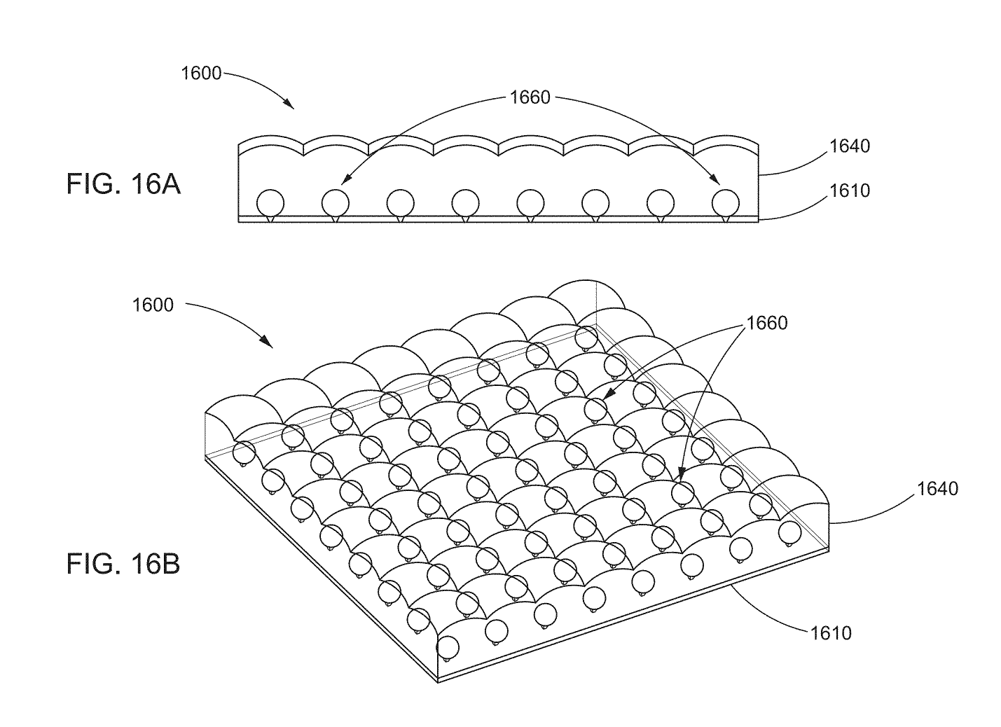

FIGS. 16A-16B show an apparatus 1600 including an array of the apparatus 1500 shown in FIGS. 15A-15B. The apparatus 1600 includes a substrate 1610 in which a plurality of cavities are fabricated. A plurality of ball lenses 1660 is disposed on or partially into the cavities. An additional concentrating layer 1640 is disposed on the ball lenses 1660.

FIGS. 16A-16B show that the ball lenses 1660 are separated from each other. In this case, the ball lenses 1660 can be disposed individually onto the substrate 1610 after the cavities are fabricated, after which the additional concentrating layer 1640 can be disposed. Alternatively, the ball lenses 1660 can be connected together by, for example, disposing the ball lenses 1660 onto a film or sandwiching the ball lenses by two films. Therefore, the ball lenses 1660 can collectively form a ball lens layer. In this case, each layer, including the substrate 1610 including the cavities, the ball lens layer, and the additional concentrating layer 1640, can be pre-fabricated and then bonded layer by layer to improve manufacturing efficiency.

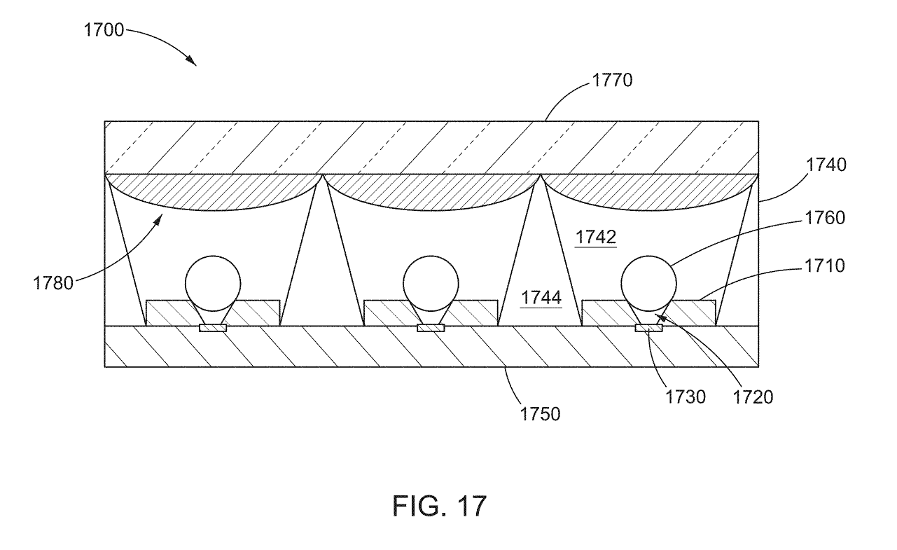

FIG. 17 shows an apparatus 1700 using the multi-functional platform for optical micro-concentration and mechanical micro-assembly to assembly multiple concentrating layers. The apparatus 1700 includes a plurality of primary substrates 1710, each of which has a cavity 1720 fabricated therein and a PV cell 1730 disposed at the bottom end of the cavity 1720. Each cavity 1720 is also coupled to a ball lens 1760, which can be self-aligned due to the matching of shapes between the cavity 1720 and the ball lens 1760. The primary substrates 1710 can be PV cells (e.g., silicon cells).

A diffuse collector 1740 is disposed on the primary substrate 1710 to direct diffuse light towards the primary substrate 1710 for electricity conversion when the primary substrate 1710 is a PV cell itself. The diffuse collector 1740 includes a first portion 1742 having a wedge shape and a second portion 1744 that is complementary to the first portion. In one example, the first portion 1742 can be filled with air and the second portion 1744 is solid. In this case, the diffuse collector 1740 can collect diffuse light by reflecting the diffuse light via the inner surface of the first portion 1742, in a manner similar to the wafer-level concentrating element described above. In another example, the first portion 1742 can also be filled with solid material, such as Ethylene-vinyl acetate (EVA) or PDMS, to enhance the mechanical stability of the apparatus 1700. In yet another example, the first portion is solid and the second portion is filled with air, in which case the diffuse collector 1740 can be substantially similar to the additional concentrating element 1240 shown in FIG. 12A. Incident light can be concentrated by total internal reflection of the first portion 1742.

A primary optical layer 1780 is disposed above the diffuse collector 1740 to focus or direct incident light toward the ball lens 1760. The primary optical layer 1780 includes a plurality of focusing surfaces, each of which corresponds to a ball lens 1760 and a cavity 1720. All the above mentioned components are sandwiched between a front substrate 1770 and a back substrate 1750 that can provide physical protection, electrical connection, and mechanical support, among other things. The primary optical layer 1780 can be directly molded on the front substrate 1770 before integration with other components, such as the diffuse collector 1740. Similarly, the diffuse collector 1740 can also be directly molded on the back substrate 1750 to facilitate manufacturing. The primary optical layer 1780 and the diffuse collector 1740 can also be pre-fabricated and subsequently assembled with other components. The front substrate 1770 can be a glass sheet. Both the front substrate 1770 and the back substrate 1750 can be flexible to allow broader applications such as in wearable technologies.

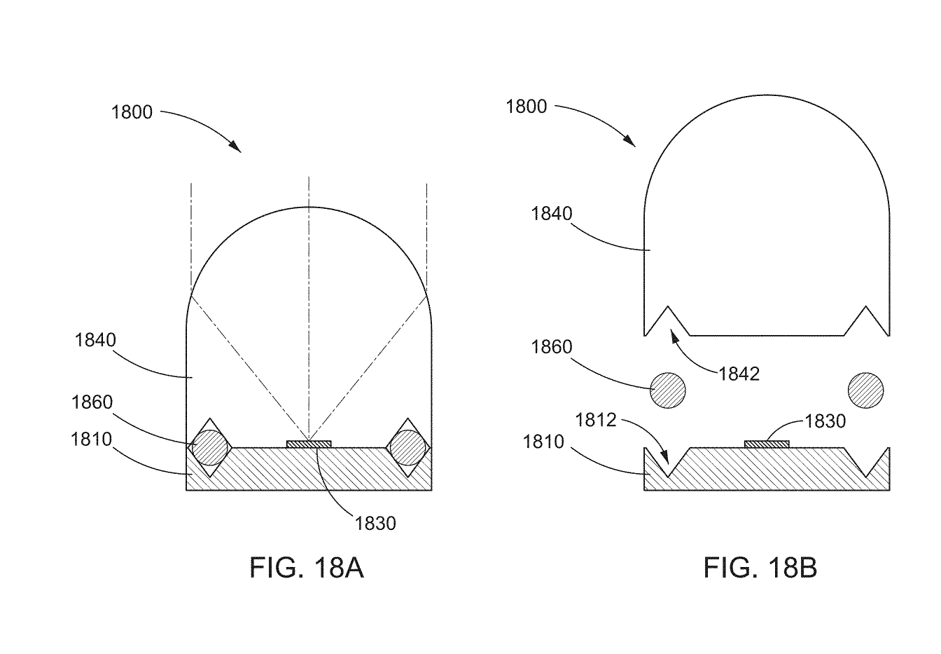

FIGS. 18A-18B show an assembled view and an exploded view of an apparatus 1800 using the multi-functional platform for alignment. The apparatus 1800 includes a substrate 1810 in which two lower alignment cavities 1812 (or grooves) are fabricated. A PV cell 1830 is disposed on the substrate 1810 to receive incident light concentrated by a concentrator 1840, which includes two upper alignment cavities 1842 at the bottom. Two ball alignment elements 1860 are disposed between the substrate 1810 and the concentrator 1840. When assembled, the top hemispheres of the two ball alignment elements 1860 are received by the upper alignment cavities 1842 and the bottom hemispheres of the two ball alignment elements 1860 are received by the lower alignment cavities 1812 in the substrate 1810. The two ball alignment elements function as a connector coupling the substrate 1810 with the concentrator 1840. Various materials can be used to make the ball alignment elements 1860, including plastic, glass, and metal. In addition, a layer of epoxy or index matching material (not shown in FIGS. 18A-18B) can be applied between the concentrator 1840 and the PV cell 1830 and/or the substrate 1810.

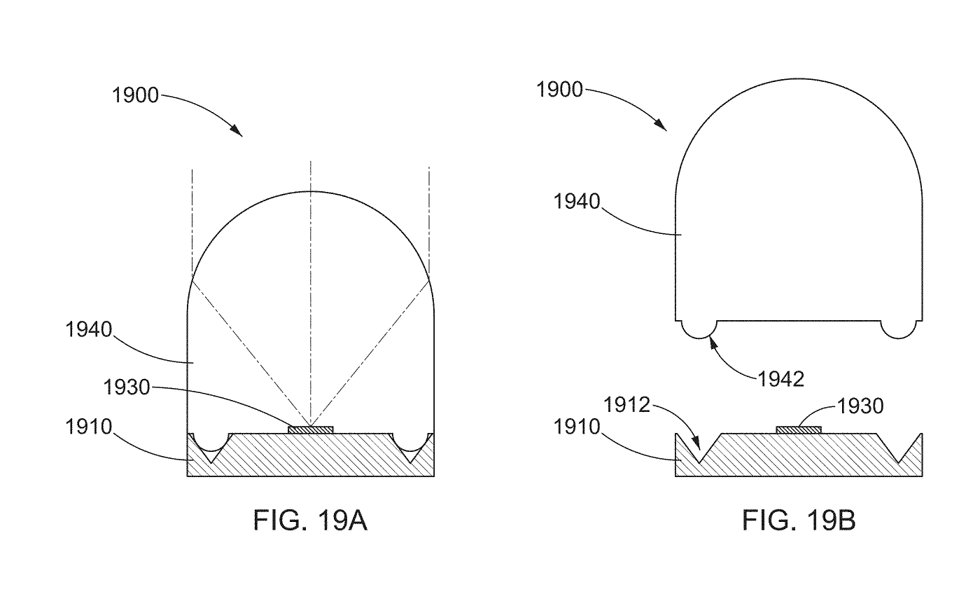

FIGS. 19A-19B show an assembled view and an exploded view of an apparatus 1900 in which alignment elements are integrated into or formed monolithically on optical components in the apparatus. More specifically, the apparatus 1900 includes a substrate 1910 in which two cavities 1912 (or grooves) are fabricated. A PV cell 1930 is disposed on the substrate 1910 to receive incident light concentrated by a concentrator 1940, which includes two alignment elements 1942 at the bottom. The two alignment elements 1942 can have a hemisphere shape and can be received by the cavities 1912 when assembled. In this case, the concentrator 1940 and the substrate 1910 can be directly aligned without the use of additional connectors.

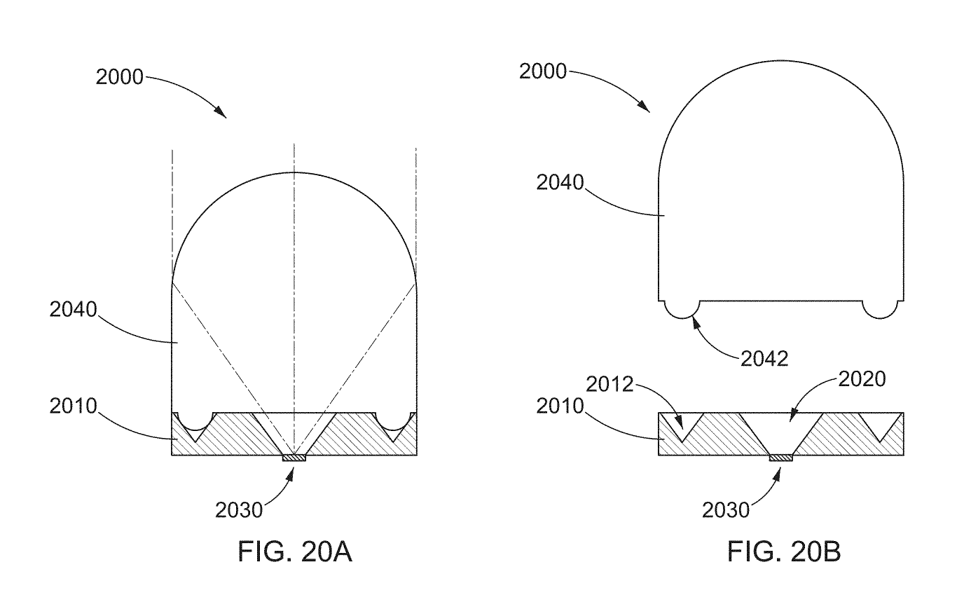

FIGS. 20A-20B show the assembled view and the exploded view of a micro-concentrating PV apparatus 2000 in which alignment elements are integrated into or formed monolithically on optical concentrators. The apparatus 2000 includes a substrate 2010, in which two lower alignment cavities 2012 and one concentrating cavity 2020 are fabricated. A PV cell 2030 is disposed at the bottom of the concentrating cavity 2020 to receive concentrated or directed incident light for electricity generation. A concentrator 2040 is disposed on the substrate 2010 to receive incident light and focus or direct the incident light toward the concentrating cavity 2020. The concentrator 2040 includes two alignment elements 2042 at the bottom, which can have a hemisphere shape and can be received by the alignment cavities 2012 when assembled.

Other Applications of Wafer-Level Multi-Functional Platform

The photovoltaic apparatus described above are examples of wafer-level multi-functional micro-platforms fabricated from semiconductor substrates. Other than photovoltaic applications, the multi-function platform can also benefit several other technologies.

In one example, the wafer-level multi-function platform can be used for optical imaging or sensing, in which the PV cells as used in apparatus shown in FIGS. 1-20B can be replaced by an imager, such as a charge-coupled-device (CCD), a complementary metal-oxide semiconductor (CMOS) device, or a photodiode (e.g., avalanche photodiode). The cavities fabricated in the substrate can concentrate light and therefore increase sensitivity of the resulting imaging/sensing apparatus.

In one example, the wafer-level multi-function platform can be used for illumination. In this case, the PV cells as used in apparatus shown in FIGS. 1-20B can be replaced by a light source (e.g., a light emitting diode (LED), lasers, or vertical-cavity surface-emitting lasers (VCSELs)). Instead of concentrating light, cavities in the substrate can manipulate (e.g., diverge or direct) light from the light source (reverse process of concentration) toward areas to be illuminated. Alternatively, the cavities can also collimate the emitted light and direct the illumination towards desired directions.

In another example, the wafer-level multi-function platform can be used for optical communication. Optical beams containing optical signals are manipulated (e.g., diverged, collimated, focused, or steered) by the cavities and other optical element described towards at least one receiver that detects the optical signals. In another example, photodetectors and light source can be integrated on the same multi-function wafer for applications such as active imaging, optical communication, sensing, etc., based on the methods and systems described above. For optical sensing, the light source emits a probing beam towards an interested region; the reflected beam is collected by the concentrated photodetector. The substrate containing the cavities can be a larger-area photodetector, which can be used to detect ambient light level.

Methods of Making Apparatus Including Wafer-Level Concentrating Elements

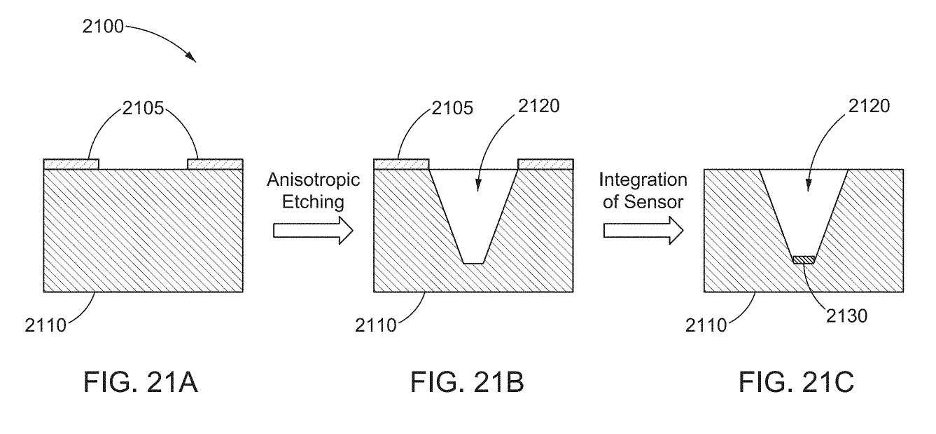

FIGS. 21A-21C illustrate a method 2100 of fabricating a PV apparatus including wafer-level concentrating elements and the multi-functional platform as used in the apparatus shown in FIGS. 1-20B. The method 2100 includes disposing a mask 2105 on the front surface of a substrate 2110, as shown in FIG. 21A. The mask 2105 has the pattern to be transferred to the substrate 2110. For example, the mask 2105 can have a square aperture for etching a pyramid cavity or a slit shape for etching a groove. The method 2100 also includes etching the substrate 2110 to form a cavity 2120, as shown in FIG. 21B. The lateral size (or aperture) of the cavity 2120 generally decreases as the etching reaches deeper into the substrate 2100. In one example, the etching can be achieved by anisotropic etching using, for example, KOH. In another example, the etching can be achieved by grey-scale lithography to form a more complex cavity shape such as free-form shapes. A PV cell 2130 is then disposed at the bottom of the cavity 2120, as shown in FIG. 21C, to form the PV apparatus. The PV cell 2130 can be placed in position by, for example, pick-and-place procedures, in which a tweezers (or other moving tool) can pick the PV cell 2130 and place it onto the desired locations. If the substrate 2110 is also a PV cell, steps for forming p-n junctions in the substrate 2110 and forming the PV cell can be performed before or after the pyramid cavities or grooves are etched.

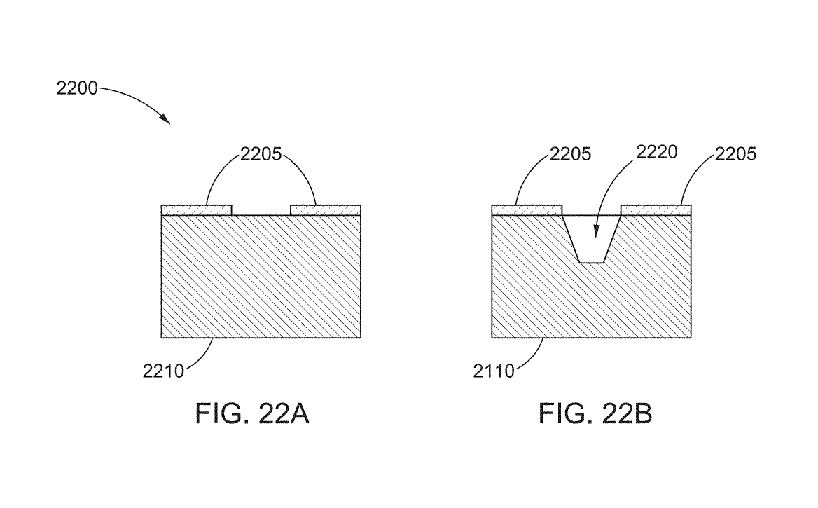

FIGS. 22A-22B illustrate fabrication of wafer-level concentrating elements in a silicon substrate using anisotropic etching. The method 2200 includes disposing a mask 2205 on the front surface of a substrate 2210, as shown in FIG. 22A. Anisotropic etching (using an etchant such as KOH) of [100] oriented (face-aligned) silicon wafers exposes the [111] crystal plane, as schematically shown in FIG. 22B, to form a cavity 2220. The [111] plane naturally makes an angle of 54.7° with respect to the [100] plane.

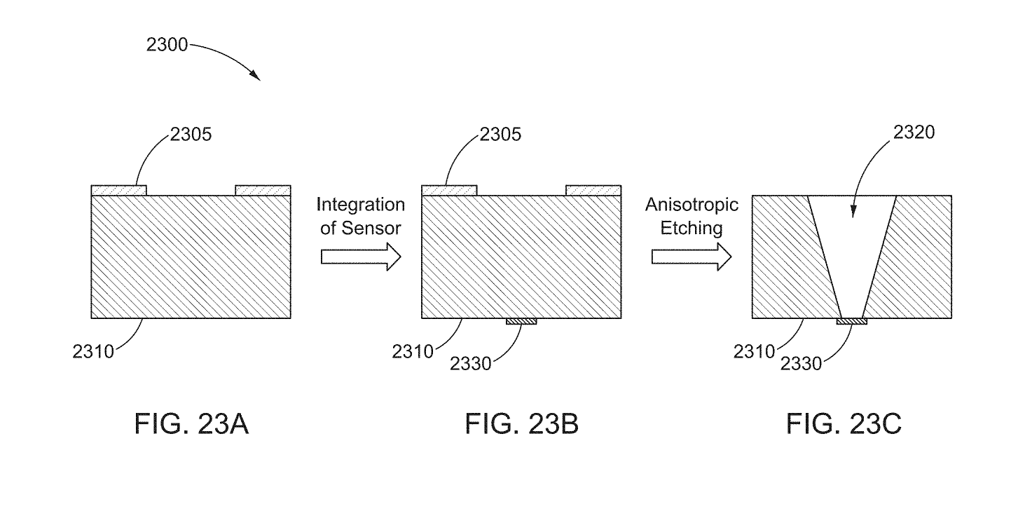

FIGS. 23A-23C illustrate a method 2300 of fabricating a PV apparatus including throughout cavities as wafer-level concentrating elements. As shown in FIG. 23A, a mask 2305 is disposed on the front surface of a substrate 2310. A PV cell 2330 is then disposed on the back surface of the substrate 2310 as shown in FIG. 23B. Etching the substrate 2310 then forms a cavity 2320 that extends from the front surface of the substrate 2310 all the way to the back surface of the substrate 2310 and reaches the PV cell 2330, thereby exposing the PV cell 2330 to incident light.

The order between integrating (e.g., by bonding) or forming the PV cell 2330 (shown in FIG. 23B) and etching the substrate 2310 (shown in FIG. 23C) can be reversed. In other words, the substrate 2310 can be etched to form the cavity 2320 before the PV cell 2330 is integrated or formed to the back surface of the substrate 2310. In one example, the substrate 2310 is also a PV cell, and steps for forming a p-n junction in the substrate 2110 and other PV cell forming steps can be performed before or after the etching process. One example process is to first etch the substrate 2310 to form the cavities, followed by steps for forming p-n junctions in the substrate 2310 and other PV cell forming steps. Then the PV cell 2330 is subsequently integrated onto the active substrate 2310 by, for example, bonding.

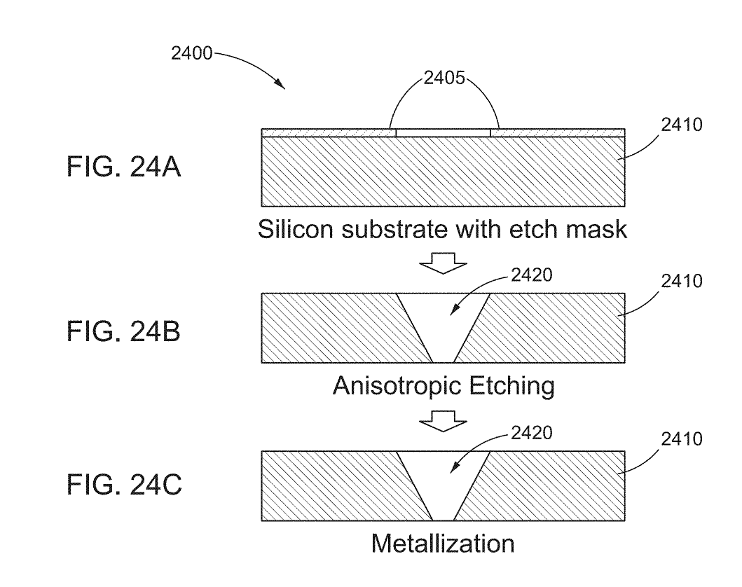

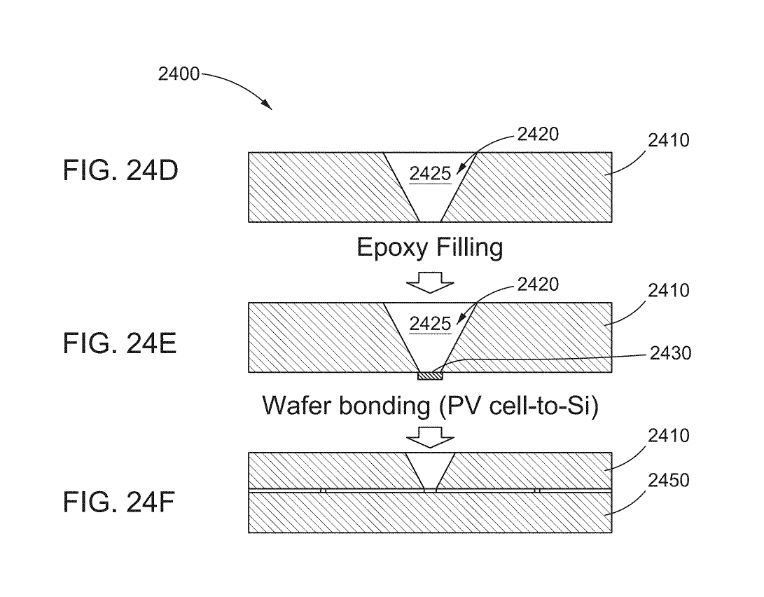

FIGS. 24A-24F illustrate a method 2400 of fabricating a PV apparatus including wafer-level concentrating elements and a back substrate. FIG. 24A shows that a silicon substrate 2410 is first prepared with an etching mask 2405 positioned to define the size and position of the desired etched facets and/or cavities. The silicon substrate 2410 may be active and/or serve as a mechanical support. Anisotropic etching is employed to create a cavity 2420 in the substrate 2410, as shown in FIG. 24B. A reflective metallization layer is subsequently deposited on the inner surfaces of the cavity 2420, as shown in FIG. 24C, to increase the reflectivity of the inner surfaces and accordingly the concentration efficiency of the cavity 2420. FIG. 24D illustrates an optional step after the metallization step shown in FIG. 23C. An epoxy layer 2425 is disposed in the cavity 2420 and planarized so as to provide mechanical support to the PV cell 2430 bonded later as shown in FIG. 24E. The PV cell 2420 can be a concentrating PV cell (e.g., multi-junction solar cells) to efficiently convert received light into electricity. After the wafer bonding step, the PV cell 1430 with wafer-level concentrators (i.e. cavity 2420) is further integrated onto a back substrate 2450 that provides further mechanical support and metal interconnections (a glass substrate, a printed circuit board, etc.), as shown in FIG. 24F.

In an alternative method for making the structure, the silicon substrate 2410 and the PV cell 2430 can be bonded together first (FIG. 24E), followed by the anisotropic etching step (FIG. 24B). Epoxy layers may be applied to provide mechanical support and/or act as an etch stop.

Additional steps can be performed on the manufactured apparatus shown in FIG. 24F to make apparatus shown in, for example, FIGS. 8A-12B. For example, direct molding of a micro-lens array on the substrate or assembly of a pre-fabricated lens array onto the substrate can be carried out to integrate additional concentrating elements (e.g., 940, 1040, and 1140 shown in FIGS. 9A, 10A, and 11A, respectively) into the apparatus. In another example, a piece of glass (e.g., about 0.1 mm to about a few mm thick) can be employed to assemble the Si platform on one side of the glass and assemble the micro-lens array on the opposite side of the glass. This approach can reduce the cost of plastic materials and improve overall robustness during the integration and assembly process.

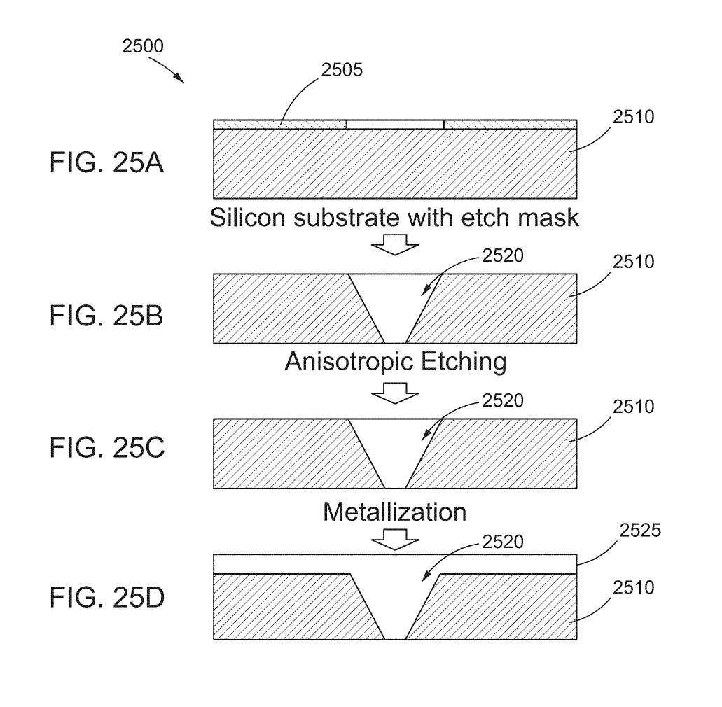

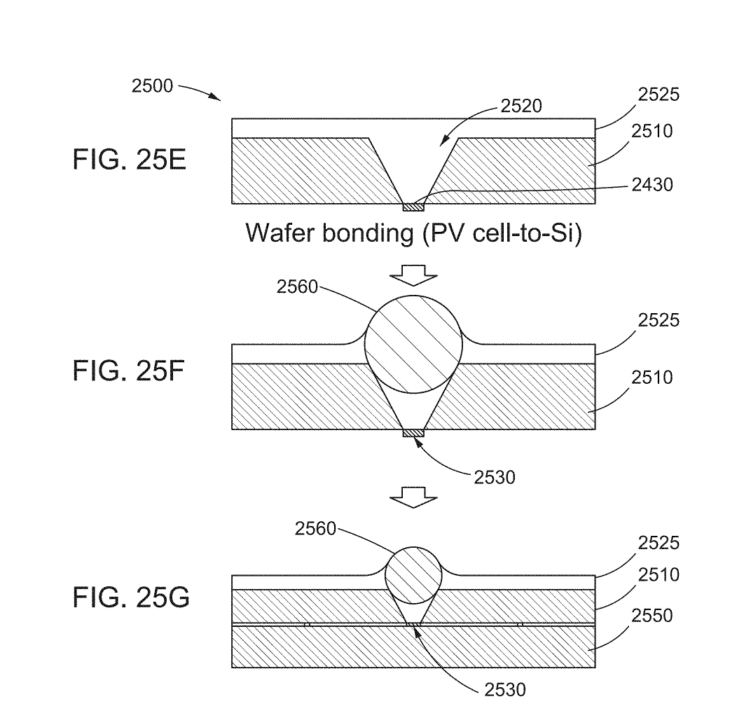

FIGS. 25A-25G illustrate a method 2500 of manufacturing a PV apparatus including alignment elements. FIG. 25A shows that a silicon substrate 2510 is first prepared with an etch mask 2505 positioned to define the size, shape, and position of the desired etched facets/cavities array. The silicon substrate 2510 can be active and/or serve as a mechanical support. As shown in FIG. 25B, an anisotropic etching is performed on the silicon substrate 2510 to create a cavity 2520. In FIG. 25C, a reflective metallization layer is deposited on the facet surfaces of the cavity 2520 to increase reflectivity. After the metallization step, an epoxy layer 2525 is flown to fill the cavity 2520 and planarized, as shown in FIG. 25D. The epoxy layer 2525 can provide mechanical supports to the PV cell 2530 bonded in next step shown in FIG. 25E. Subsequently, as shown in FIG. 25F, a ball lens 2560 is disposed in the cavity 2420 by, for example, picking and placing. The cavity 2520 can align and hold the ball lens 2560 in position. FIG. 25G shows that after the wafer bonding or the ball lens assembly step, the PV cell 2530 with wafer-level concentrators (i.e., cavity 2520) is further integrated onto a back substrate 2550 that provides further mechanical support and conductive interconnections (a glass substrate, a printed circuit board, etc.). In an alternative method, the electrical interconnections can be formed directly on the silicon substrate 2510.

Characterization of Apparatus Including Wafer-Level Concentrating Elements

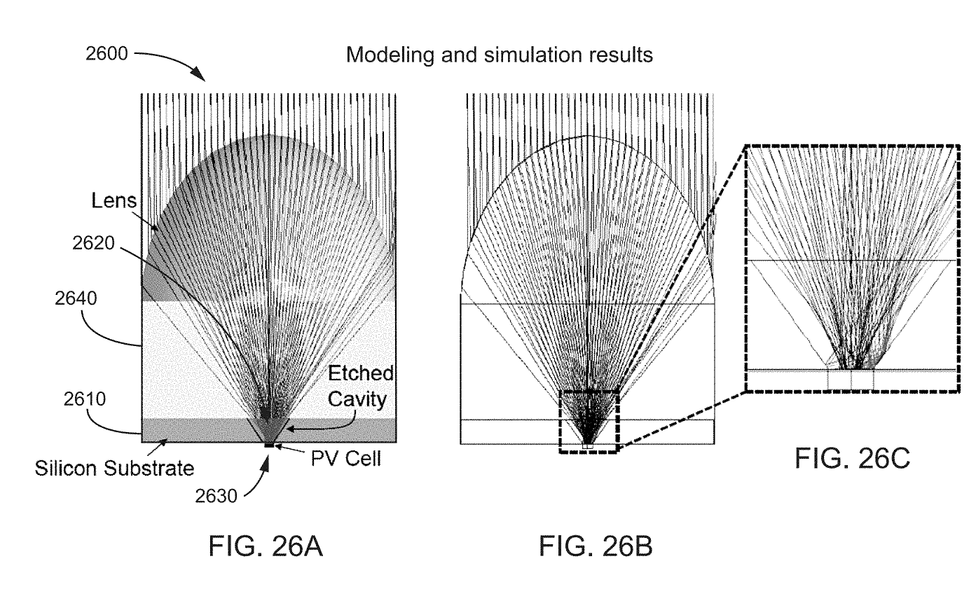

The approaches and concepts described above can be modeled and simulated with optical ray-tracing. FIGS. 26A-26C shows simulation results of an exemplary wafer-level concentrating PV system 2600, including the ray traces of light incident on the system. The PV system includes a substrate 2610 in which a cavity 2620 is etched as the wafer-level concentrating element. The cavity 2620 is a rectangular cavity with 35.3° facets in the x- and y-directions. The cavity 2620 is also filled with silicone and the etched facets are coated with silver. A PV cell 2630 is disposed at the lower end of the cavity 2620 to receive incident light concentrated by the cavity 2620. An additional concentrating element 2640 is disposed on the substrate 2610 to receive incident light and focuses or directs the incident light toward the entrance of the cavity 2620. Silicone can be used to form the additional concentrating element 2640 because it is directly moldable and flexible. The geometric concentration between the input aperture of the additional concentrating element 2640 and the PV cell 2630 is about 500 ×.

The optical structure can be simulated with a 3D non-sequential Monte Carlo ray-trace, under a light source with AM 1.5 solar spectrum and a half-degree divergence angle, simulating the direct irradiation from the sun. Simulations yield acceptance angles of ±2° and ±2.5° at 90% and 50% (FWHM) of the peak transmission, respectively. At the same acceptance angle, the concentration ratio that can be achieved by similar optical materials and structures without the reflective cavity is about 200×. Therefore, simulation results indicate that the simple optical design with naturally-formed silicon cavity can provide a considerable improvement on the concentration ratio (e.g., more than 2× usage reduction of costly multi junction PV cells) while maintaining a reasonable acceptance angle tolerant to most low-cost trackers (1° ˜1.5° tracking accuracy). The silicon substrate 2610 can be made a PV cell as well to collect and convert diffuse light and light out the concentrator's field-of-view into electrical power.

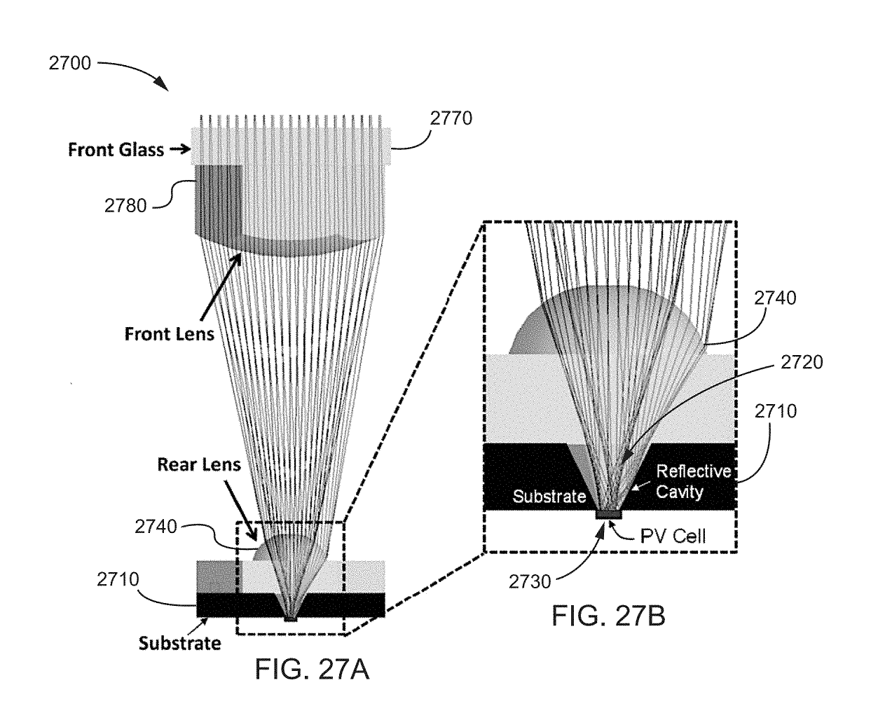

FIGS. 27A-27C show simulation results of a two-stage optical system that can further improve the “concentration x acceptance angle” product (see, e.g., equation (1) below) and meanwhile significantly reduce hot spot effects using advanced lens surface design and the reflective cavity structure. The system 2700 includes a substrate 2710, in which a cavity 2720 is fabricated. A PV cell 2730 is attached to the back surface of the substrate 2710. The optical concentration of the system 2700 includes a rear lens 2740 and a front lens 2780 bonded to a front glass 2770. Ray traces shown in FIGS. 27A-27B indicate that nearly all the incident light reaches the PV cell 2730 for electricity generation. In another example, toroidal or other free-form shaped front and rear lens surfaces can be utilized to improve illumination uniformity, reduce hot spot, and improve collection efficiency.

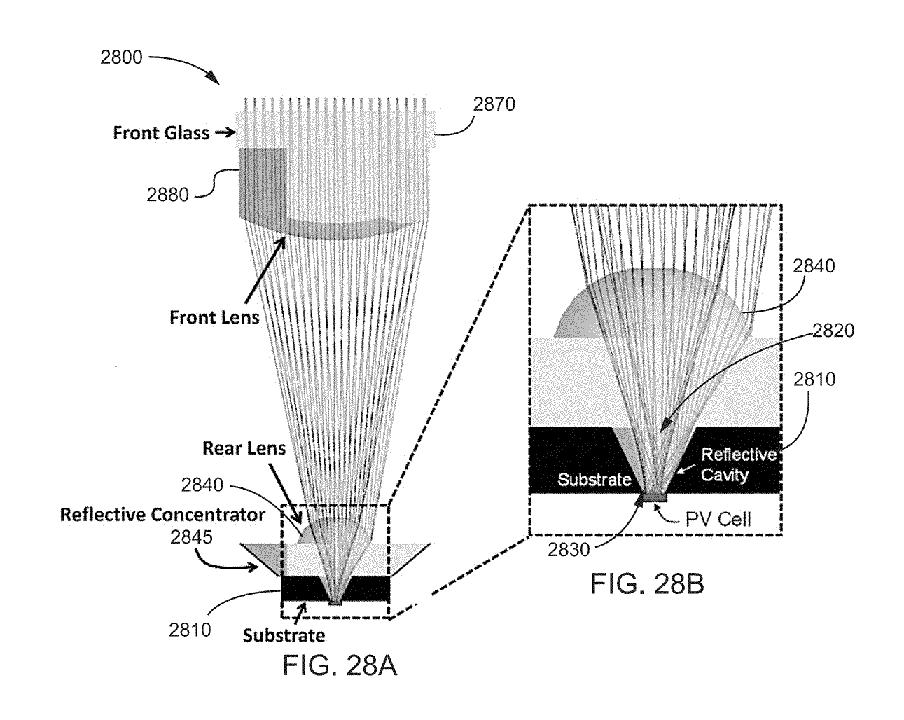

FIGS. 28A-28B show simulation results of a PV system including an additional concentrator compared to the system shown in FIGS. 27A-27C. The system 2800 includes a substrate 2810, in which a cavity 2820 is fabricated. A PV cell 2830 is attached to the back surface of the substrate 2810. The system 2800 includes a rear lens 2840 and a front lens 2880 bonded to a front glass 2870. The system 2800 further includes an additional concentrator 2845 that can concentrate the incident light enough that a low-concentration substrate cell may be used. As shown in FIG. 28A, the portion of the rear lens 2840 above the substrate 2810 can be configured to be a reflective concentrator 2845 via either reflective coatings or total internal reflection on the concentrator side surface 2846. Such a configuration can be applied to all the examples described in this application. In this case, the substrate 2810 can have a low concentration (instead of 1×) but still collect most of the light not collected by the concentrated PV cell 2830, such as diffuse light.

The approaches described in this application are projected to at least double the dollars per Watt of state-of-the-art micro-scale CPV. To evaluate concentrator PV systems, an effective merit function is the concentration-acceptance product:

CAP=\sqrt{C_{g}}sinθᵢₙ (1)

where C_{g} is the concentration ratio and θᵢₙ is the acceptance angle. In general, CAP is nearly invariant for a given optical architecture. State-of-the-art CPV technologies typically have a CAP between 0.4 and 0.6, making such CPV modules either not cost effective due to insufficient concentration or require high-accuracy but costly trackers due to small acceptance angles. In contrast, the single-lens baseline system (e.g., shown in FIGS. 26A-26C, C_{g}=500×, θᵢₙ=±2°) achieves a CAP of 0.78 with an optical system thickness less than 5 mm. The baseline system is fully compatible with low-cost trackers having a tracking accuracy of about 1° to about 1.5° in manufacturing.

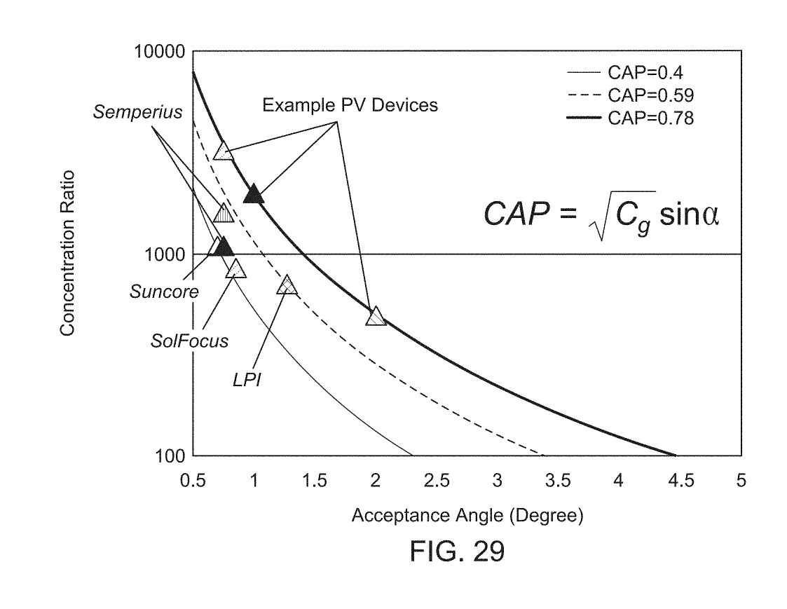

A second baseline system for high-concentration can achieve an acceptance angle of ±1° at a concentration of 2000×. A third baseline system for high-concentration can achieve an acceptance angle of ±0.75° at a concentration of ˜3300×. In another exemplary system based on the 2-stage optical concentrator concept (e.g., shown in FIGS. 27A-27B), a CAP of ˜0.85 can be achieved, yielding concentrations of 600× and 2700×, acceptance angles of ±2° and ±1°, respectively. Compared with existing technologies, the disclosed approach can reduce the cost of multi junction cells and optical components by more than 50% with improved tolerance to angular misalignment and a simplified compact optical architecture that can further reduce assembly costs. In addition, the single-lens baseline design also allows the flexibility to be revised into advanced optical designs with additional optical element(s) at low cost that further increase CAP. Comparisons of baseline systems of the disclosed approach to state-of-the-art micro-/mini-CPV technologies are shown in Table 1 and FIG. 29.

TABLE 1
Comparison of baseline systems with existing
small-form-factor CPV technologies

| | | | | | Exam- | Exam- |
|---|---|---|---|---|---|---|
| | Suncore | SolFocu | Sempriu | LPI | ple 1 | ple 2 |
| Concentration | 1090X | 850X | 1600X | 710X | 500X | 3300X |
| Acceptance | ±0.7° | ±0.85° | ±0.75° | ±1.27° | ±2° | ±0.75° |
| Angle | | | | | | |
| CAP | 0.4 | 0.43 | 0.52 | 0.59 | 0.78 | 0.75 |
| Element Count | 2 | 2 | 2 | 2 | 1 | 1 |

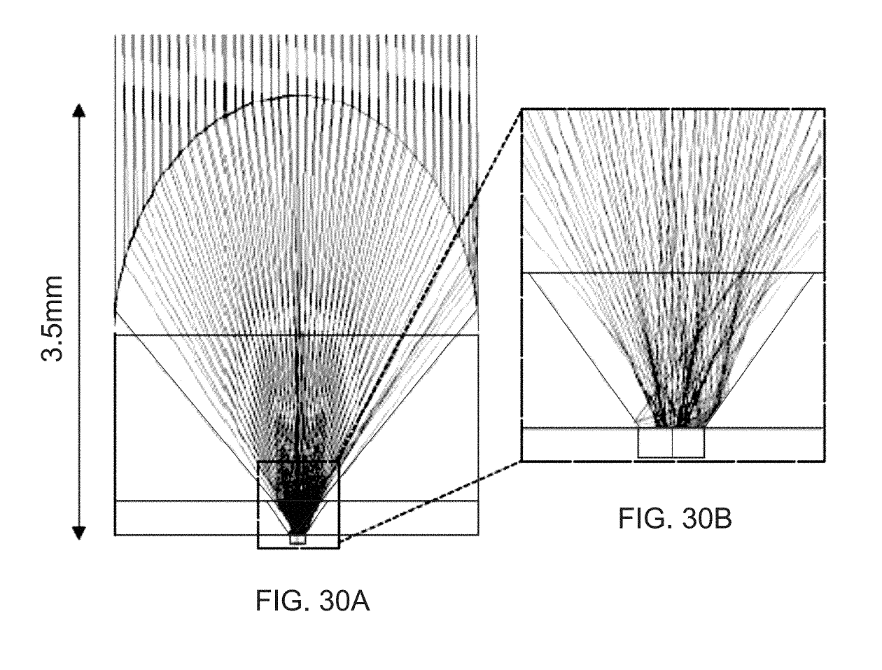

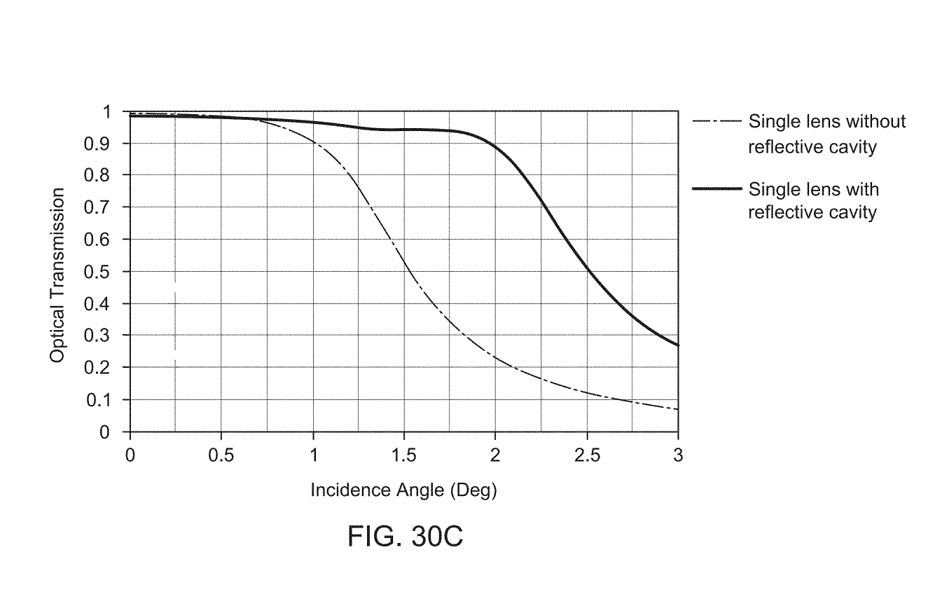

FIGS. 30A-30C show simulation results of a PV system including wafer-level concentrating elements with simulation results of a similar system without any wafer-level concentrating elements. In this system, a single silicone lens is positioned on top of a silicon substrate which contains an inverted-pyramid-shaped rectangular cavity defined by facets with a slanting angle of 35.3°. The cavity is filled with silicone and the etched facets are coated with silver. A PV cell is located at the bottom of the cavity. The optical system is simulated using 3D non-sequential Monte Carlo ray-trace, under a light source with AM 1.5 solar spectrum and a half-degree divergence angle. Ray-trace simulation of a baseline system yields a geometric concentration of 500× with an acceptance angle of ±2° (at 90% of the maximum transmission) and a total thickness of ˜3.5 mm. The modeling results indicate that the simple optical design with anisotropically etched silicon cavity provides a desirable concentration ratio while maintaining a reasonable acceptance angle compatible with low-cost trackers (1° ˜1.5° tracking accuracy). The same lens design without the reflective cavity is also simulated and yields an acceptance angle of ±1° (shown in FIG. 30C), indicating that the etched Si cavity increases the field-of-view of a conventional optical concentrator.

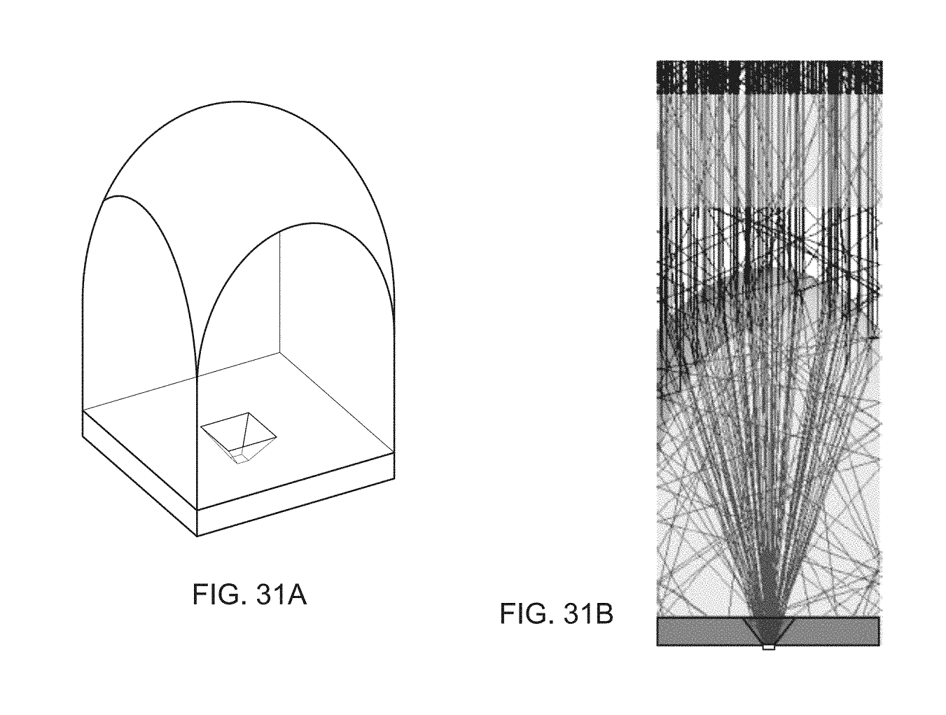

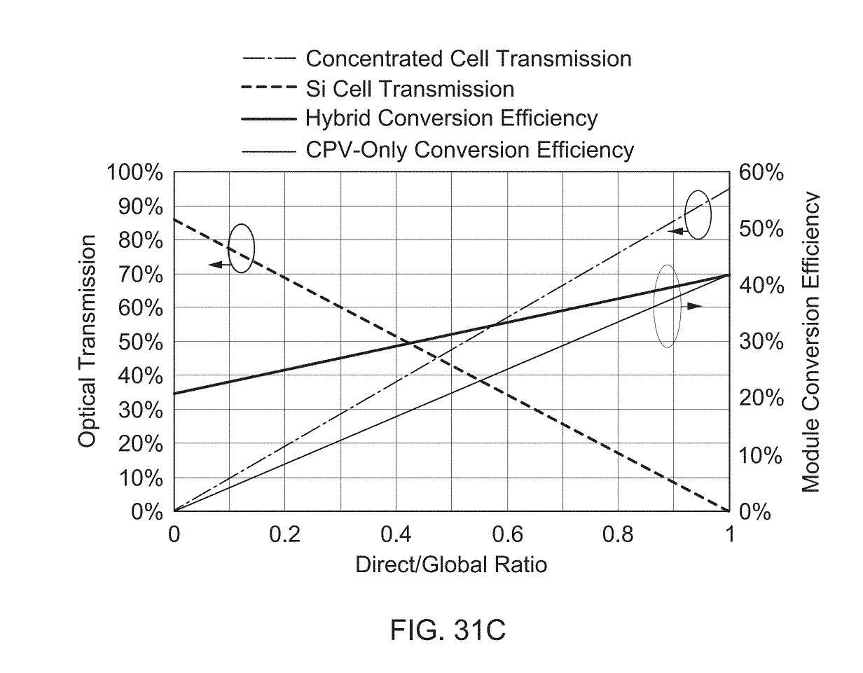

FIGS. 31A-31C show the modeling and simulation of an exemplary system under simulated direct and diffuse light with a variety of direct/global irradiation ratios, representing different geological and weather scenarios. Assuming a 4-junction concentrated cell efficiency of 44% and a Si cell efficiency of 24%, the overall conversion efficiency of the hybrid module is projected and compared to a CPV-only case of the same concentrator but without the Si cell (i.e. wafer-level concentrating element). Between 0.75˜0.6 Direct/Global irradiation ratio, the hybrid module provides a conversion efficiency improvement of 17% to 33% from the CPV-only case. Note that even at regions in the U.S. with abundant solar irradiation, approximately 20% of the total annual radiation comes from diffuse light which cannot be collected by conventional CPV technologies.

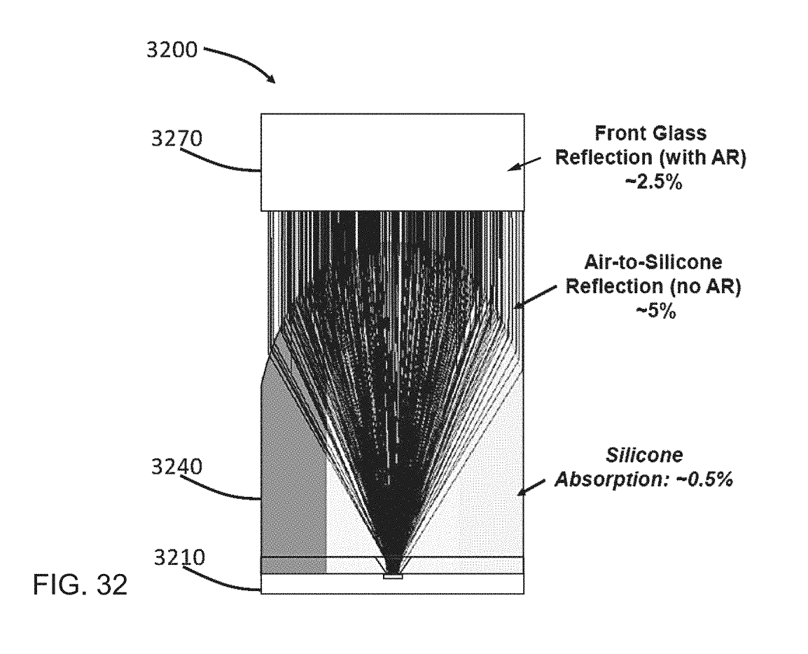

According to the optical simulations, the overall optical transmission of a baseline system 3200 covered by an AR-coated front glass can be about 92%, as shown in FIG. 32 with a breakdown of the optical losses. The system 3200 includes a substrate 3210 for fabricating the wafer-level concentrating element and attaching PV cells. A lens 3240 is disposed on the substrate 3210 to focus incident light onto the entrance of the wafer-level concentrating element. A front glass piece 3270 is employed for physical protection of the system 3200. The scattering loss is estimated to be about 0.2% based on previously fabricated parts. With appropriate AR layers, the transmission of such an optical module to the PV cell is estimated to be greater than 94%. The projected component and module efficiencies of the disclosed approach in a full module (assuming a 3× concentration Si cell that further reduces materials costs) is summarized in Table 3. It is clearly indicated that even at regions with high diffuse irradiation (40%), the hybrid architecture with high-concentration multi junction micro-cells and low-concentration Si cells (3×) can still achieve a conversion efficiency of over 30%, enabling expanded utilization of CPV technologies in regions once deemed unsuitable for CPV installation.

TABLE 3
Projected component and module efficiencies

| Parameter | Symbol | Value | Estimated variation |
|---|---|---|---|
| Fractional DNI | f_{DNI} | 60% | |
| Opt. Eff. (Direct) | ηₒₚₜ_{_{—}}_{DNI} | 94% | <0.02 |
| Opt. Eff. (Diffuse) | ηₒₚₜ_{_{—}}_{Diffuse} | 56% | <0.001 |
| DNI PV Eff. | η_{PV}_{_{—}}_{DNI} | 44% | 0.02 |
| Diffuse PV Eff. | η_{PV}_{_{—}}_{Diffuse} | 24% | 0.02 |
| Solar Harvesting Eff. | η_{Harvest}_{_{—}}_{DC} | 30.2% | 0.04 |

Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of designing and making the technology disclosed herein may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes (outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A photovoltaic (PV) apparatus comprising:
a substrate having a first substrate surface and a second substrate surface, the substrate defining at least one cavity extending from the first substrate surface toward the second substrate surface, the at least one cavity defining:
a first end to receive incident light;
a second end opposite the first end; and
a side surface, extending from the first end to the second end, to concentrate the incident light, received by the first end, toward the second end; and
a PV cell, in optical communication with the second end of the at least one cavity, to convert the incident light into electricity.

2. The PV apparatus of claim 1, wherein the substrate comprises a p-n junction to collect diffuse light.

3. The PV apparatus of claim 1, wherein the at least one cavity comprises an array of cavities having a pitch of about 0.1 mm to about 100 mm.

4. The PV apparatus of claim 3, further comprising:
an array of micro-lenses, disposed on the first substrate surface of the substrate, to focus the incident light onto the array of cavities.

5. The PV apparatus of claim 4, wherein the array of micro-lenses is flexible.

6. The PV apparatus of claim 1, wherein the side surface defines at least a portion of at least one of a pyramid, a paraboloid, a sphere, or a cone.

7. The PV apparatus of claim 1, wherein the PV cell has a lateral dimension of about 10 μm to about 2 mm.

8. The PV apparatus of claim 1, wherein the PV cell comprises a multi junction PV cell.

9. The PV apparatus of claim 1, further comprising:
a reflective coating, disposed on the side surface of the cavity, to reflect the incident light toward the PV cell.

10. The PV apparatus of claim 1, further comprising:
another PV cell, disposed on the side surface of the cavity, to collect diffuse light.

11. The PV apparatus of claim 1, further comprising:
a first concentrating element, in optical communication with the first substrate surface of the substrate, to focus the incident light toward the cavity.

12. The PV apparatus of claim 11, wherein the first concentrating element comprises at least one of Polydimethylsiloxane or Poly(methyl methacrylate).

13. The PV apparatus of claim 11, wherein the first concentrating element comprises a diffractive optic.

14. The PV apparatus of claim 11, further comprising:
another PV cell, disposed on the first substrate surface of the substrate, to receive diffuse light.

15. The PV apparatus of claim 11, further comprising:
a second concentrating element, disposed in optical communication with the first concentrating element and the first end of the cavity, to receive the incident light focused by the first concentrating element.

16. The PV apparatus of claim 15, wherein the first concentrating element has a first refractive index and the second concentrating element has a second refractive index greater than the first refractive index.

17. The PV apparatus of claim 15, wherein the second concentrating element comprises a ball lens disposed at least partially in the at least one cavity.

18. The PV apparatus of claim 1, further comprising:
a first concentrating element, in optical communication with the first substrate surface of the substrate, to focus the incident light toward the cavity;
an alignment element, disposed at least partially within the cavity, to align the first concentrating element with the substrate; and
another PV cell, disposed on the first substrate surface of the substrate, to receive diffuse light.

19. The PV apparatus of claim 18, wherein the alignment element comprises a ball lens.

20. A method of making a photovoltaic (PV) device, the method comprising:
etching a substrate to form at least one cavity extending from a first substrate surface of the substrate toward a second substrate surface of the substrate, the at least one cavity defining:
a first end to receive incident light;
a second end opposite the first end; and
a side surface, extending from the first end to the second end, to concentrate the incident light received by the first end toward the second end; and
coupling a PV cell to the second end of the at least one cavity.

21. The method of claim 20, wherein etching the substrate comprises etching a silicon substrate via anisotropic etching.

22. The method of claim 21, wherein the anisotropic etching of the silicon substrate comprises etching along a (111) plane of the silicon substrate so as to form at least a portion of the side surface of the at least one cavity.

23. The method of claim 20, wherein etching the substrate comprises defining a bottom surface of the at least one cavity and wherein coupling the PV cell comprises disposing the PV cell on the bottom surface of the at least one cavity.

24. The method of claim 20, wherein etching the substrate comprises etching the at least one cavity through the substrate, and wherein coupling the PV cell comprises disposing the PV cell at least partially on the second substrate surface of the substrate.

25. The method of claim 20, wherein etching the substrate comprises forming an array of cavities in the substrate, the array of cavities having a pitch of about 1 mm to about 10 mm.

26. The method of claim 25, further comprising:
disposing an array of micro-lenses in optical communication with the array of cavities.

27. The method of claim 20, further comprising:
disposing another PV cell on the first substrate surface of the substrate; and
disposing a concentrating element over the second PV cell and the at least one cavity.

28. The method of claim 20, further comprising:
depositing a reflective coating on the side surface of the at least one cavity.

29. The method of claim 20, further comprising:
disposing a dielectric material in the at least one cavity to define an acceptance angle of the PV device to be greater than 1.5°.

30. A photovoltaic (PV) device comprising:
a silicon substrate having a first substrate surface and a second substrate surface, the silicon substrate defining an array of cavities having a pitch of about 1 mm to about 10 mm, each cavity in the array of cavities extending from the first substrate surface toward the second substrate surface and defining:
a first end to receive the incident light;
a second end; and
a side surface to concentrate the incident light received by the first end toward the second end;
an array of multi junction PV cells, disposed in optical communication with the second end of a respective cavity in the array of cavities, to convert the incident light into electricity; and
a micro-lens array, disposed on the first substrate surface, to focus incident light toward the array of cavities.
